(19) United States
(12) Patent Application Publication
(10) Pub. No.: US 2024/0295614 A1
(43) Pub. Date: Sep. 5, 2024

(54) SPEAKER SHORT TO POWER AND GROUND DIAGNOSTICS

(71) Applicant: Texas Instruments Incorporated, Dallas, TX (US)

(72) Inventors: Weiyu Shen, Shanghai (CN); Douglas A Roberson, Royse City, TX (US); Rong Rong, Shanghai (CN); Shurong Xia, Plano, TX (US)

(21) Appl. No.: 18/214,375

(22) Filed: Jun. 26, 2023

Related U.S. Application Data
(60) Provisional application No. 63/449,840, filed on Mar. 3, 2023.

(51) Int. Cl. G01R 31/52; H02H 1/00; H03F 1/52; H04R 29/00

(52) U.S. Cl. CPC G01R 31/52; H02H 1/0007; H03F 1/52; H04R 29/001

(57) ABSTRACT

Example systems, apparatus, articles of manufacture, and methods are disclosed to implement speaker short to power and ground diagnostics for amplifier circuits. An example circuit disclosed herein includes short detection circuitry having an input adapted to be coupled to an output of an amplifier, and an output, to sense an output current from the output of the amplifier and filter a signal corresponding to the output current from the output of the amplifier to measure a direct current (DC) offset associated with the output current, wherein the short detection circuitry output indicates a short at the output of the amplifier based on the DC offset.

### CROSS-REFERENCE TO RELATED APPLICATION

This patent application claims the benefit of and priority to U.S. Provisional Patent Application No. 63/449,840 filed Mar. 3, 2023. U.S. Provisional Patent Application No. 63/449,840 is hereby incorporated herein by reference in its entirety.

### TECHNICAL FIELD

This disclosure relates generally to amplifier circuits and, more particularly, to speaker short to power and ground diagnostics for amplifier circuits.

### BACKGROUND

Switching amplifiers, also referred to as class-D amplifiers, are routinely used to drive speakers in audio systems. For example, switching amplifiers are used to drive speakers in automobile audio systems, mobile devices (e.g., such as smartphones, tablet computers, etc.), home theater systems, hearing aids, etc. Over time, such audio systems can suffer wear and/or damage, which may result in a short circuit (e.g., a direct short or a weak short corresponding to a low resistance connection) from one or more of the amplifier outputs to power or ground. Such a short circuit can cause damage to the switching amplifier and/or other components of the audio system.

### SUMMARY

For methods and apparatus to implement speaker short to power and ground diagnostics for amplifier circuits, an example circuit includes short detection circuitry having an input adapted to be coupled to an output of an amplifier, and an output, to sense an output current from the output of the amplifier and filter a signal corresponding to the output current from the output of the amplifier to measure a direct current (DC) offset associated with the output current, wherein the short detection circuitry output indicates a short at the output of the amplifier based on the DC offset.

For methods and apparatus to implement speaker short to power and ground diagnostics for amplifier circuits, an example switching amplifier includes a positive amplifier output, a negative amplifier output and short detection circuitry including current sense circuitry having a first current sense input, a first current sense output, a second current sense input, and a second current sense output. The short detection circuitry also includes multiplexer circuitry having a first multiplexer input to couple to the first current sense output, a second multiplexer input to couple to the second current sense output, and a multiplexer output. The short detection circuitry further includes filter circuitry to filter a signal generated on the multiplexer output to measure a direct current (DC) offset associated with the multiplexer output, and fault detection circuitry having a fault output to indicate a short on at least one of the positive amplifier output or the negative amplifier output, wherein the fault detection circuitry determines the fault output based on the DC offset.

For methods and apparatus to implement speaker short to power and ground diagnostics for amplifier circuits, an example switching amplifier includes short detection circuitry including first current sense circuitry having a first current sense input and a first current sense output, the first current sense input coupled to a positive amplifier output, the first current sense output to output a first sensed current associated with the positive amplifier output. The short detection circuitry also includes second current sense circuitry having a second current sense input and a second current sense output, the second current sense input coupled to a negative amplifier output, the second current sense output to output a second sensed current associated with the negative amplifier output. The short detection circuitry further includes first filter circuitry to filter a first signal generated on the first current sense output to measure a first direct current (DC) offset associated with the first sensed current, and second filter circuitry to filter a second signal generated on the second current sense output to measure a second DC offset associated with the second sensed current. The short detection circuitry also includes fault detection circuitry having a fault output to indicate detection of a short on at least one of the positive amplifier output or the negative amplifier output, wherein the fault detection circuitry determines the fault output based on the first DC offset and the second DC offset.

### BRIEF DESCRIPTION OF THE DRAWINGS

FIG. 1 is a block diagram of an example environment in which example short detection circuitry operates to provide short to power and ground diagnostics in accordance with teachings of this disclosure.

FIG. 2 is a block diagram of a first example implementation of the short detection circuitry of FIG. 1.

FIG. 3 is a block diagram of a second example implementation of the short detection circuitry of FIG. 1.

FIG. 4 is a flowchart representative of first example machine readable instructions and/or example operations that may be executed, instantiated, and/or performed using an example programmable circuitry implementation of the short detection circuitry of FIG. 2.

FIG. 5 is a flowchart representative of second example machine readable instructions and/or example operations that may be executed, instantiated, and/or performed using an example programmable circuitry implementation of the short detection circuitry of FIG. 3.

FIG. 6 is a block diagram of an example processing platform including programmable circuitry structured to execute, instantiate, and/or perform the example machine readable instructions and/or perform the example operations of FIGS. 4 and/or 5 to implement the short detection circuitry of FIGS. 2 and/or 3.

FIG. 7 is a block diagram of an example implementation of the programmable circuitry of FIG. 6.

FIG. 8 is a block diagram of another example implementation of the programmable circuitry of FIG. 6.

FIG. 9 is a block diagram of an example software/firmware/instructions distribution platform (e.g., one or more servers) to distribute software, instructions, and/or firmware (e.g., corresponding to the example machine readable instructions of FIGS. 4 and/or 5) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts, elements, etc. The figures are not necessarily to scale.

### DETAILED DESCRIPTION

Example systems, apparatus, articles of manufacture, and methods are disclosed to implement speaker or, more generally, output short to power and ground diagnostics for amplifier circuits. As mentioned above, switching amplifiers (e.g., class-D amplifiers) are routinely used to drive the speakers of audio systems, such as automobile audio systems, mobile devices (e.g., such as smartphones, tablet computers, etc.), home theater systems, hearing aids, etc. Over time, such audio systems may develop short circuit conditions from one or more of the amplifier outputs to power or ground. Such short circuit conditions include a full or complete short circuit corresponding to a direct connection from an amplifier output to power or ground, a weak short circuit corresponding to a low resistance connection from an amplifier output to power or ground, etc., which are collectively referred to herein as short circuit conditions, short circuits, short conditions or shorts.

As noted above, short circuits from amplifier outputs to power or ground can cause damage to the switching amplifier and/or other components of the audio system. In some examples, such damage can be severe if unchecked due to the power being output from the switching amplifier. Furthermore, depending on the type of audio system and/or application in which the audio system is used, such damage can be costly and/or raise safety concerns, both of which may be unacceptable to manufacturers and users alike.

Example systems, apparatus, articles of manufacture, and methods disclosed herein implement and utilize short detection circuitry to provide short to power and ground diagnostics for amplifier circuits. Example short detection circuitry implemented in accordance with teachings of this disclosure monitors the outputs of a switching amplifier to detect short conditions during system operation (e.g., in real-time). Example short detection circuitry implemented in accordance with teachings of this disclosure also outputs one or more fault diagnostics to enable identification of the short condition and/or shutdown of the amplifier and/or other system components to prevent, reduce or otherwise mitigate damage to the amplifier and/or other system components. Example short detection circuitry disclosed herein can also detect a full or complete short circuit corresponding to a direct connection from an amplifier output to power or ground, as well as a weak short circuit corresponding to a low resistance connection from an amplifier output to power or ground.

In examples in which the amplifier includes both positive and negative outputs, example short detection circuitry disclosed herein monitors both the positive output for a short condition to power or ground, and the negative output for a short condition to power or ground. In some examples, the short detection circuitry includes multiplexer functionality to switch between monitoring the positive amplifier output and monitoring the negative amplifier output to reuse circuit components and, thus, achieve a low cost, low power and small footprint circuit design. Additionally, or alternatively, in some examples, the short detection circuitry includes one or more adjustable thresholds that can tailor short circuit detection to the particular type of amplifier monitored by the short detection circuitry.

These and other example methods, apparatus, systems and articles of manufacture (e.g., physical storage media) to implement speaker or, more generally, output short to power and ground diagnostics for amplifier circuits are disclosed in further detail below.

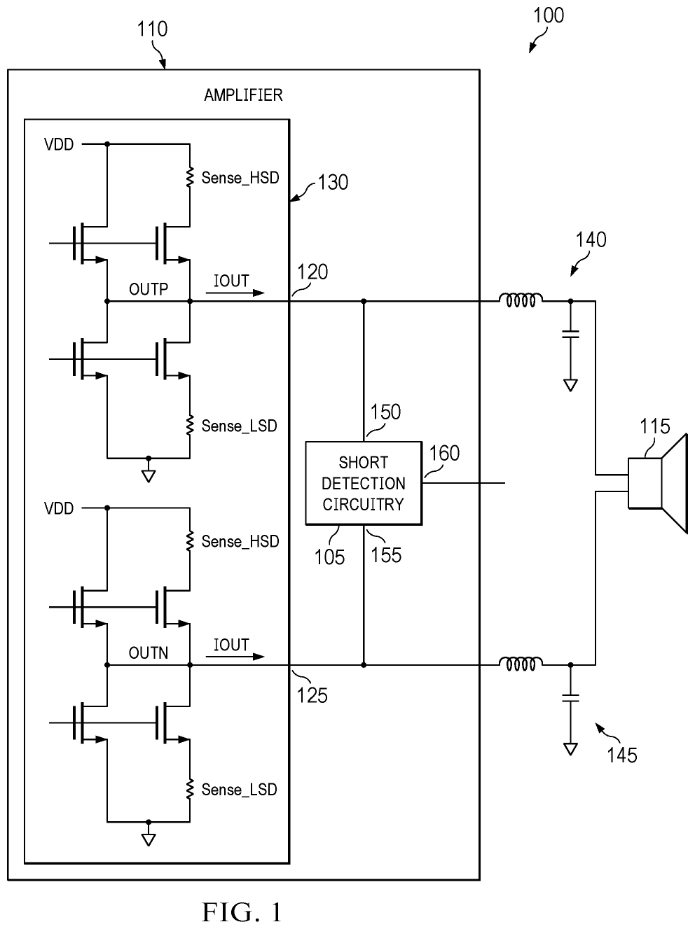

FIG. 1 is a block diagram of an example environment 100 in which example short detection circuitry 105 operates to implement speaker or, more generally, output short to power and ground diagnostics for an example amplifier 110 in accordance with teachings of this disclosure. The example environment 100 corresponds to an example audio system 100 that includes an example speaker 115 that is driven by the amplifier 110. In the illustrated example, the amplifier 110 is a switching amplifier, also referred to as a class D amplifier, that has an example positive output 120 and an example negative output 125. In general, switching amplifiers are designed to generate a train of rectangular pulses that are modulated based on an input audio signal applied to the amplifier to produce an amplified output signal. The amplified output signal is applied to a low pass filter to generate an amplified output audio signal used to drive a speaker, such as the speaker 115. In the illustrated example, the switching amplifier 110 includes example circuitry 130 to generate a train of rectangular pulses that are modulated based on an input audio signal applied to the amplifier, as previously described. The example circuitry 130 of the switching amplifier 110 is also structured to produce a positive output current at the positive output 120 and a negative output current at the negative output 125 that are inverses of each other. For example, the circuitry 130 of the switching amplifier 110 can be implemented by the circuitry of any of a host of switching, or class D, amplifiers, such as those manufactured by Texas Instruments Incorporated. In the example audio system 100 of FIG. 1, the positive output 120 of the switching amplifier 110 and the negative output 125 of the switching amplifier 110 are coupled to respective example low pass filters 140 and 145, which are coupled to respective inputs of the speaker 115.

The example short detection circuitry 105 of FIG. 1 has an example positive input 150 to couple or otherwise connect to the positive output 120 of the amplifier 110, and an example negative input 155 to couple or otherwise connect to the negative output 125 of the amplifier 110. The example short detection circuitry 105 of FIG. 1 also has an example fault output 160 to output fault diagnostics associated with detected short circuit conditions. In the illustrated example of FIG. 1, the short detection circuitry 105 is included in the amplifier 110 (e.g., included in the same package as the amplifier 110). In other examples, the short detection circuitry 105 can be implemented as circuitry separate from, but configured to couple or otherwise connect to, the amplifier 110 (e.g., in a package separate from the package of the amplifier 110).

The example short detection circuitry 105 of FIG. 1 monitors the positive output current at the positive output 120 and the negative output current at the negative output 125 to detect short circuit conditions at either or both of the positive output 120 and/or the negative output 125 of the switching amplifier 110. In the illustrated example of FIG. 1, to detect short circuit conditions, the short detection circuitry 105 determines a direct current (DC) offset of the positive output current at the positive output 120, referred to herein as the positive output DC offset of the amplifier 110, and a DC offset of the negative output current at the negative output 125, referred to herein as the negative output DC offset of the amplifier 110. The short detection circuitry 105 of the illustrated example then uses the positive output DC offset to detect a short circuit condition at the positive output 120, and uses the negative output DC offset to detect a short circuit condition at the negative output 125.

For example, the short detection circuitry 105 may compare the positive output DC offset to one or more thresholds to detect a short to ground at the positive output 120 or a short to power at the positive output 120. In some examples, the short detection circuitry 105 may compare the negative output DC offset to one or more thresholds to detect a short to ground at the negative output 125 or a short to power at the negative output 125. In some examples, different thresholds may be used to detect short to ground conditions versus short to power conditions. In some examples, the same threshold may be used to detect short to ground conditions and short to power conditions. In some examples, different thresholds may be compared against the positive output DC offset versus the negative output DC offset. In some examples, the same threshold may be compared against the positive output DC offset and negative output DC offset.

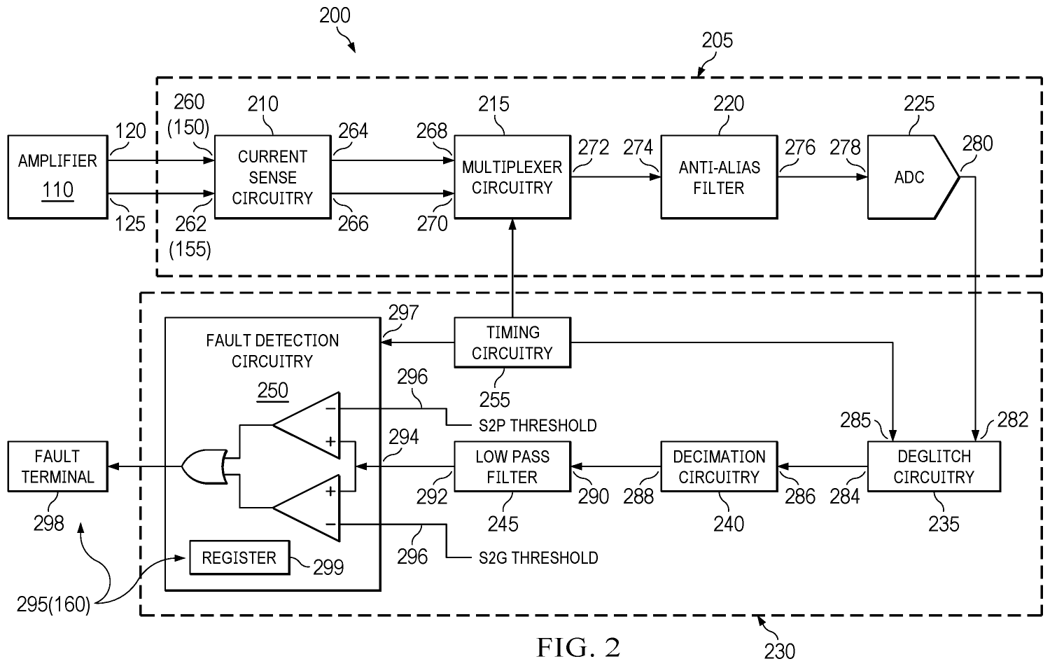

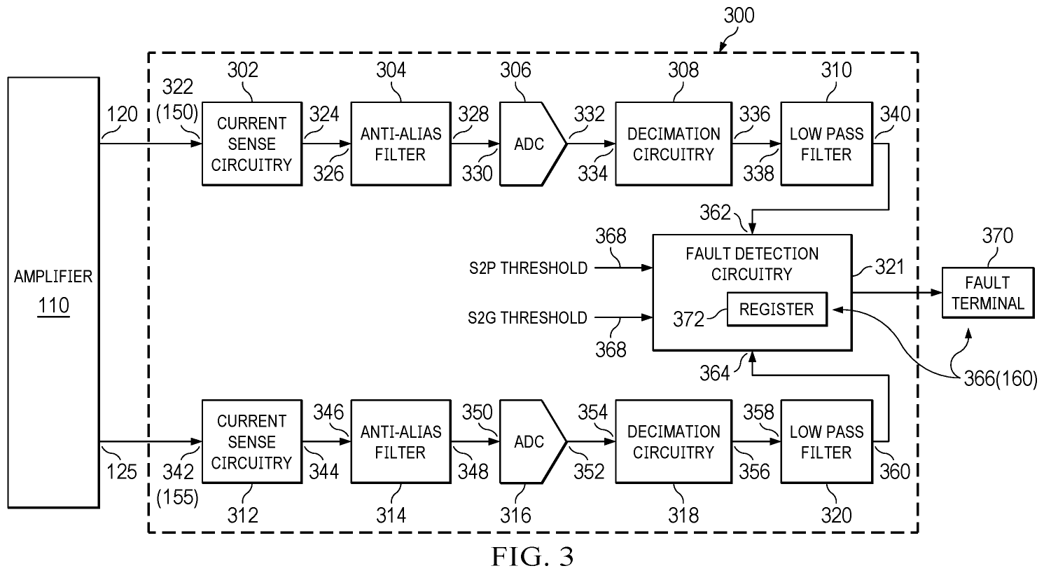

In some examples, the thresholds are set (e.g., adjusted, preconfigured, programmable, etc.) based on a type of the amplifier 110. For example, different types of switching amplifier may utilize generate trains of rectangular pulses with different duty cycles. In some such examples, the threshold(s) utilized by the short detection circuitry 105 can be set (e.g., adjusted, preconfigured, etc.) based on the duty cycle utilized by the amplifier 110. In some examples, additional or alternative characteristics of the type of the amplifier 110 may be used to set (e.g., adjusted, preconfigured, programmable, etc.) the threshold(s) utilized by the short detection circuitry 105. Example implementations of the short detection circuitry 105 are illustrated in FIGS. 2 and 3.

FIG. 2 is a block diagram of a first example implementation 200 of the short detection circuitry 105 of FIG. 1. The short detection circuitry 200 of FIG. 2 may be instantiated (e.g., creating an instance of, bring into being for any length of time, materialize, implement, etc.) by programmable circuitry such as a Central Processor Unit (CPU) executing first instructions. Additionally, or alternatively, the short detection circuitry 105 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

Turning to FIG. 2, the short detection circuitry 200 illustrated therein includes example analog circuitry 205, which includes example current sense circuitry 210, example multiplexer circuitry 215, an example anti-alias filter 220 and an example analog-to-digital converter (ADC) 225. The example short detection circuitry 200 of FIG. 2 also includes example digital circuitry 230, which includes example deglitch circuitry 235, example decimation circuitry 240, an example low pass filter 245, example fault detection circuitry 250 and example timing circuitry 255. The example current sense circuitry 210 has an example positive current sense input 260 to couple to the positive amplifier output 120 of the amplifier 110, and an example negative current sense input 262 to couple to the negative amplifier output 125 of the amplifier 110. As such, in the illustrated example, the current sense input 260 corresponds to the positive input 150 of the short detection circuitry 105 and the negative current sense input 262 corresponds to the negative input 155 of the short detection circuitry 105. The current sense circuitry 210 of the illustrated example is structured to sense the current applied to the positive current sense input 260, which corresponds to the positive output current at the positive output 120 of the amplifier 110, and to sense the current applied to the negative current sense input 262, which corresponds to the negative output current at the negative output 125 of the amplifier 110. The current sense circuitry 210 further has an example positive current sense output 264 to output the sensed current associated with positive current sense input 260, which corresponds to the positive output current at the positive output 120 of the amplifier 110, and an example negative current sense output 266 to output the sensed current associated with negative current sense input 262, which corresponds to the negative output current at the negative output 125 of the amplifier 110.

The example multiplexer circuitry 215 of FIG. 2 has an example positive multiplexer input 268 to couple to positive current sense output 264 of the current sense circuitry 210. The multiplexer circuitry 215 also has an example negative multiplexer input 270 to couple to negative current sense output 266 of the current sense circuitry 210. The multiplexer circuitry 215 further has an example multiplexer output 272. The multiplexer circuitry 215 of the illustrated example is structured to switch (e.g., repeatedly, periodically, etc.) between connection of the multiplexer output 272 to the positive multiplexer input 268 and connection of the multiplexer output 272 to the negative multiplexer input 270. In the illustrated example, the switching performed by the multiplexer circuitry 215 is controlled via an example multiplexer timing input 273 of the multiplexer circuitry 215. Inclusion of the multiplexer circuitry 215 in the example short detection circuitry 200 of FIG. 2 enables downstream circuit elements of the short detection circuitry 200 (e.g., such as the anti-alias filter 220, the ADC 225, the deglitch circuitry 235, the decimation circuitry 240, the low pass filter 245, etc.) to be reused for evaluating both the sensed current associated with the positive output 120 of the amplifier 110 and the sensed current associated with the negative output 125 of the amplifier 110, thereby reducing the footprint (e.g., size, power consumption, cost, etc.) of the short detection circuitry 200. For example, the multiplexer circuitry 215 repeatedly switches between providing the sensed current at the positive output 120 of the amplifier 110 and providing the sensed current at the negative output 125 of the amplifier 110 downstream to a single ADC 225,

[symbol]

The example anti-alias filter 220 of FIG. 2 has an example filter input 274 to couple to the multiplexer output 272 of the multiplexer circuitry 215. The anti-alias filter 220 also has an example filter output 276. The anti-alias filter 220 of the illustrated example is structured to restrict the bandwidth of the sensed current signal output from the multiplexer circuitry 215 based on the sampling rate employed by the ADC 225 to thereby reduce or eliminate aliasing effects in the digital data produced by the ADC 225.

The example ADC 225 of FIG. 2 has an example ADC input 278 to couple to the filter output 276 of the anti-alias filter 220. The ADC 225 also has an example ADC output 280. The ADC 225 of the illustrated example is structured to convert an analog signal applied to the ADC input 278 to a digital signal produced at the ADC output 280. For example, the ADC 225 can implement a sigma-delta ADC, a successive approximation register (SAR) ADC, etc. In the illustrated example, the analog signal applied to the ADC input 278 corresponds to the sensed current signal provided by the multiplexer output 272 of the multiplexer circuitry 215, and the digital signal produced at the ADC output 280 corresponds a digital signal representative of the sensed current signal provided by the multiplexer output 272 of the multiplexer circuitry 215.

The example deglitch circuitry 235 of FIG. 2 has an example deglitch input 282 to couple to the ADC output 280 of the ADC 225. The deglitch circuitry 235 also has an example deglitch output 284. In the illustrated example, the deglitch circuitry 235 is structured to reduce potential glitches in digital signal produced at the ADC output 280. Such glitches can result from the multiplexer circuitry 215 switching between outputting the sensed current associated the positive output 120 of the amplifier 110 and outputting the sensed current associated the negative output 125 of the amplifier 110. For example, the deglitch circuitry 235 can be structured to perform delay compensation and sample-and-hold operations on the digital signal produced at the ADC output 280 to produce a deglitched digital signal at the deglitch output 284, which corresponds to a deglitched digital signal representative of the sensed current signal provided by the multiplexer output 272 of the multiplexer circuitry 215. In the illustrated example, operation of the deglitch circuitry 235 is synchronized with operation of the multiplexer circuitry 215 via an example deglitch timing input 285 of the deglitch circuitry 235.

The example decimation circuitry 240 of FIG. 2 has an example decimation input 286 to couple to the deglitch output 284 of the deglitch circuitry 235. The decimation circuitry 240 also has an example decimation output 288. In the illustrated example, the decimation circuitry 240 is structured to perform decimation, or down-sampling, of an input digital signal applied to the decimation input 286 to produce a down-sampled digital signal at the decimation output 288 with a reduced sampling rate relative to the sampling rate of the input digital signal. As such, the down-sampled digital signal at the decimation output 288 corresponds to a down-sampled digital signal representative of the sensed current signal provided by the multiplexer output 272. Inclusion of the decimation circuitry 240 in the example short detection circuitry 200 of FIG. 2 enables downstream circuit elements of the short detection circuitry 200 (e.g., such as the low pass filter 245, etc.) to operate at a reduced sampling rate, thereby reducing the power consumption of those circuit elements. However, in some examples, the decimation circuitry 240 is not included in the short detection circuitry 200.

The example low pass filter 245 of FIG. 2 has an example filter input 290 to couple to the decimation output 288 of the decimation circuitry 240. The low pass filter 245 also has an example filter output 292. In the illustrated example, the low pass filter 245 is structured to filter the digital signal applied to the filter input 290 to generate an output value at the filter output 292 representative of the DC offset of the input digital signal. As such, the low pass filter 245 may have a relatively low cutoff frequency, such as less than or equal to 10 Hertz (Hz) or some other suitable cutoff frequency. As the digital signal applied to the filter input 290 corresponds to the sensed current signal provided by the multiplexer output 272 of the multiplexer circuitry 215, the output value at the filter output 292 corresponds to the DC offset of the sensed current signal provided by the multiplexer output 272 of the multiplexer circuitry 215. Thus, when the multiplexer circuitry 215 is switched to output the sensed current associated the positive output 120 of the amplifier 110, the output value at the filter output 292 corresponds to the DC offset of the sensed current associated the positive output 120 of the amplifier 110. Likewise, when the multiplexer circuitry 215 is switched to output the sensed current associated the negative output 125 of the amplifier 110, the output value at the filter output 292 corresponds to the DC offset of the sensed current associated the negative output 125 of the amplifier 110.

The example fault detection circuitry 250 of FIG. 2 has an example detection input 294 to couple to the filter output 292 of the low pass filter 245. The fault detection circuitry 250 also has an example fault output 295, which corresponds to the fault output 160 of the short detection circuitry 105 of FIG. 1. In the illustrated example, the fault detection circuitry 250 is structured to set the fault output 160 to signal detection of a short associated with at least one of the positive amplifier output 120 or the negative amplifier output 125. The fault detection circuitry 250 is also structured to detect such a short circuit condition based on the DC offset determined by the low pass filter 245. For example, the fault detection circuitry 250 may be structured to detect a short circuit condition based on comparison of the DC offset to one or more example thresholds 296. As noted above, when the multiplexer circuitry 215 is switched to output the sensed current associated the positive output 120 of the amplifier 110, the DC offset determined by the low pass filter 245 corresponds to the DC offset of the sensed current associated the positive output 120 of the amplifier 110, referred to herein as the positive output DC offset of the amplifier 110. Likewise, when the multiplexer circuitry 215 is switched to output the sensed current associated the negative output 125 of the amplifier 110, the DC offset determined by the low pass filter 245 corresponds to the DC offset of the sensed current associated the negative output 125 of the amplifier 110, referred to herein as the negative output DC offset of the amplifier 110. Thus, when the multiplexer circuitry 215 is switched to output the sensed current associated the positive output 120 of the amplifier 110, the fault output 295 signals whether a short circuit condition has been detected for the positive amplifier output 120 based on the positive output DC offset of the amplifier 110. Likewise, when the multiplexer circuitry 215 is switched to output the sensed current associated the negative output 125 of the amplifier 110, the fault output 295 signals whether a short circuit condition has been detected for the negative amplifier output 125 based on the negative output DC offset of the amplifier 110. In the illustrated example, operation of the fault detection circuitry 250 is synchronized with operation of the multiplexer circuitry 215 via an example detector timing input 297 of the fault detection circuitry 250.

As described above, the fault detection circuitry 250 may compare the input DC offset to one or more example thresholds 296 to detect a short circuit condition associated with the positive amplifier output 120 and/or the negative amplifier output 125 of the amplifier 110. As also described above, in some examples, the same threshold 296 may be used to detect short to ground conditions and short to power conditions. However, in some examples, different thresholds 296 may be used to detect short to ground conditions versus short to power conditions. As also described above, in some examples, the same threshold 296 may be compared against the positive output DC offset and the negative output DC offset to detect short circuit conditions associated with positive amplifier output 120 and/or the negative amplifier output 125. However, in some examples, different thresholds 296 may be compared against the positive output DC offset versus the negative output DC offset to detect short circuit conditions associated with positive amplifier output 120 and/or the negative amplifier output 125. As further described above, in some examples, the thresholds 296 are set (e.g., adjusted, preconfigured, programmable, etc.) based on a type of the amplifier 110.

For example, the threshold(s) 296 may be calculated based on Equation 1. which is:

$${Offset}_{Isense} = \frac{PVDD - PVDD \times DutyCycle}{{R}_{short}} \qquad Equation 1$$

In Equation 1, PVDD is the supply voltage used to power the amplifier 110, DutyCycle is the duty cycle of the rectangular pulse train generated by the amplifier 110, Rₛₕₒᵣₜ is the value of the resistance associated with a short circuit condition, and Offset_{Isense} is the resulting DC offset that would be observed if the short circuit condition characterized by the resistance Rₛₕₒᵣₜ was present at the amplifier output corresponding to the measured DC offset Offset_{Isense}. Thus, if Rₛₕₒᵣₜ is set to a resistance value corresponding to the weakest short circuit condition to be detected, then the value of Offset_{Isense} determined by Equation 1 corresponds to a threshold that can be used to detect that short circuit condition.

In an example implementation in which the amplifier 110 is a switching amplifier 110 characterized by a 50% duty cycle for its rectangular pulse train, a single threshold 296 (e.g., of 1.5 amperes (A) or some other value) is used by the fault detection circuitry 250 to set the fault output 295 as follows:
(1) if the positive output DC offset has a negative polarity and a magnitude that satisfies (e.g., is equal to or greater than) the threshold 296, set the fault output 295 to indicate a short to power condition exists at the positive amplifier output 120;
(2) if the positive output DC offset has a positive polarity and a magnitude that satisfies (e.g., is equal to or greater than) the threshold 296, set the fault output 295 to indicate a short to ground condition exists at the positive amplifier output 120;
(3) if the negative output DC offset has a positive polarity and a magnitude that satisfies (e.g., is equal to or greater than) the threshold 296, set the fault output 295 to indicate a short to power condition exists at the negative amplifier output 125;
(4) if the negative output DC offset has a negative polarity and a magnitude that satisfies (e.g., is equal to or greater than) the threshold 296, set the fault output 295 to indicate a short to ground condition exists at the negative amplifier output 120; and
(5) otherwise, set the fault output 295 to indicate no short circuit condition has been detected.

In another example implementation in which the amplifier 110 is a switching amplifier 110 characterized by a 15% duty cycle for its rectangular pulse train, multiple thresholds 296 including a first threshold (e.g., of 2.5 A or some other value) and a second threshold (e.g., of 0.5 A or some other value) are used by the fault detection circuitry 250 to set the fault output 295 as follows:
(1) if the positive output DC offset has a negative polarity and a magnitude that satisfies (e.g., is equal to or greater than) the first threshold 296, set the fault output 295 to indicate a short to power condition exists at the positive amplifier output 120;
(2) if the positive output DC offset has a positive polarity and a magnitude that satisfies (e.g., is equal to or greater than) the second threshold 296, set the fault output 295 to indicate a short to ground condition exists at the positive amplifier output 120;
(3) if the negative output DC offset has a positive polarity and a magnitude that satisfies (e.g., is equal to or greater than) the first threshold 296, set the fault output 295 to indicate a short to power condition exists at the negative amplifier output 125;
(4) if the negative output DC offset has a negative polarity and a magnitude that satisfies (e.g., is equal to or greater than) the second threshold 296, set the fault output 295 to indicate a short to ground condition exists at the negative amplifier output 120; and
(5) otherwise, set the fault output 295 to indicate no short circuit condition has been detected.

In the illustrated example, the fault output 295 of the fault detection circuitry 250 includes an example fault terminal 298 and an example register 299. However, in some examples, the fault output 295 can include multiple terminals instead of, or in addition to, the fault terminal 298 and the example register 299. In the illustrated example, the fault detection circuitry 250 sets the fault terminal 298 to a first logic value to indicate a short condition has been detected, sets the fault terminal 298 to a second logic value to indicate no short condition has been detected and sets the register 299 to a register value to indicate the type of short condition detected. For example, the fault detection circuitry 250 can operate to set the register 299 as follows:
(1) set the register 299 to a first value to indicate a short to power condition exists at the positive amplifier output 120;
(2) set the register 299 to a second value to indicate a short to ground condition exists at the positive amplifier output 120;
(3) set the register 299 to a third value to indicate a short to power condition exists at the negative amplifier output 125; and
(4) set the register 299 to a fourth value to indicate a short to ground condition exists at the negative amplifier output 120.

The example timing circuitry 255 of FIG. 2 is structured to provide timing outputs to the multiplexer timing input 273 of the multiplexer circuitry 215, the deglitch timing input 285 of the deglitch circuitry 235 and the detector timing input 297 of the fault detection circuitry 250 to synchronize operation of the multiplexer circuitry 215, the deglitch circuitry 235 and the fault detection circuitry 250. For example, the timing circuitry 255 can include one or more counters, timers, etc., and/or other digital logic to generate control signals to cause the multiplexer circuitry 215, the deglitch circuitry 235 and the fault detection circuitry 250 to periodically switch between processing of the sensed current associated with the positive output 120 of the amplifier 110 and the sensed current associated with the negative output 125 of the amplifier 110 based on a measurement period.

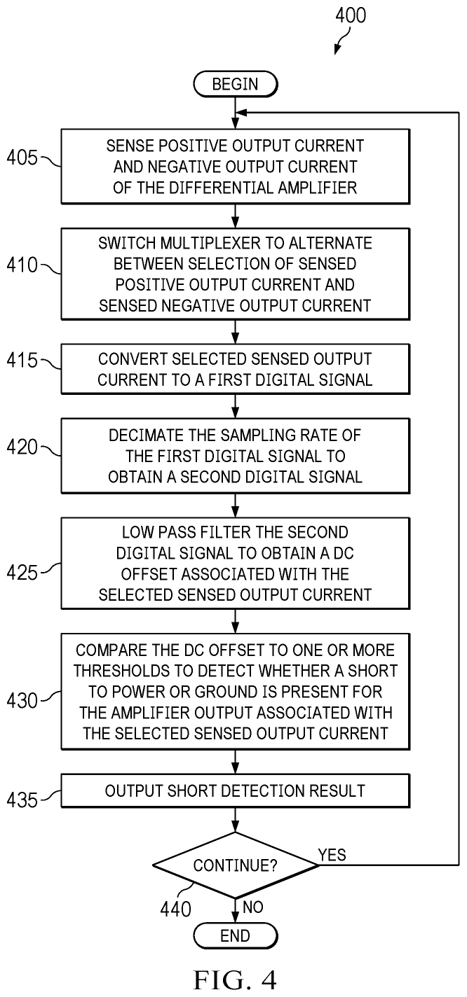

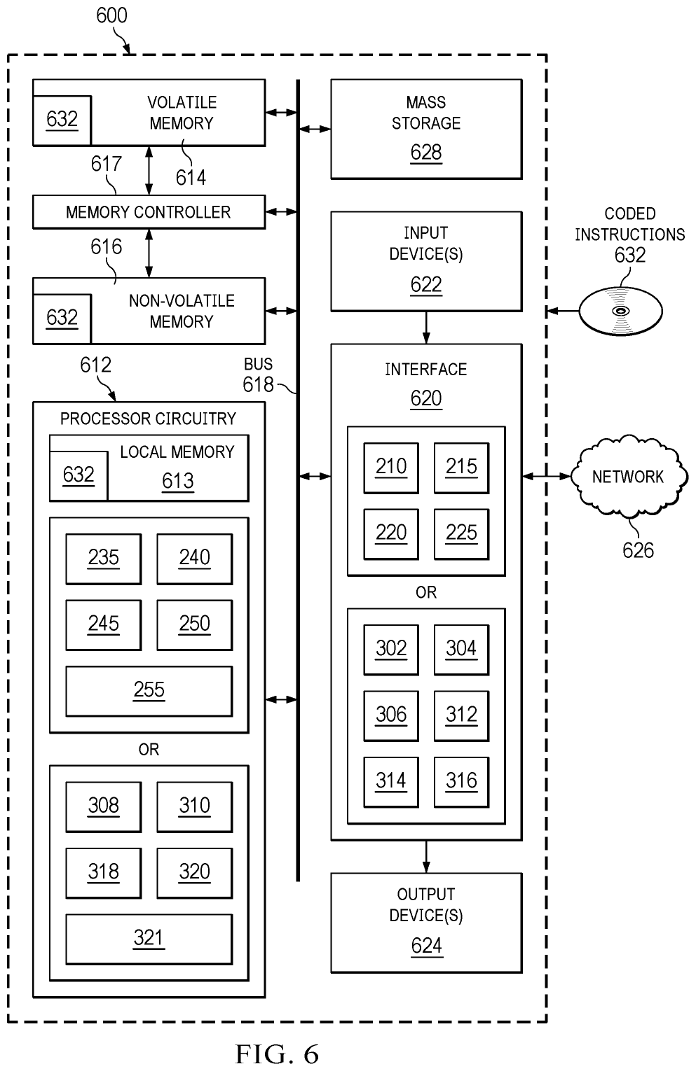

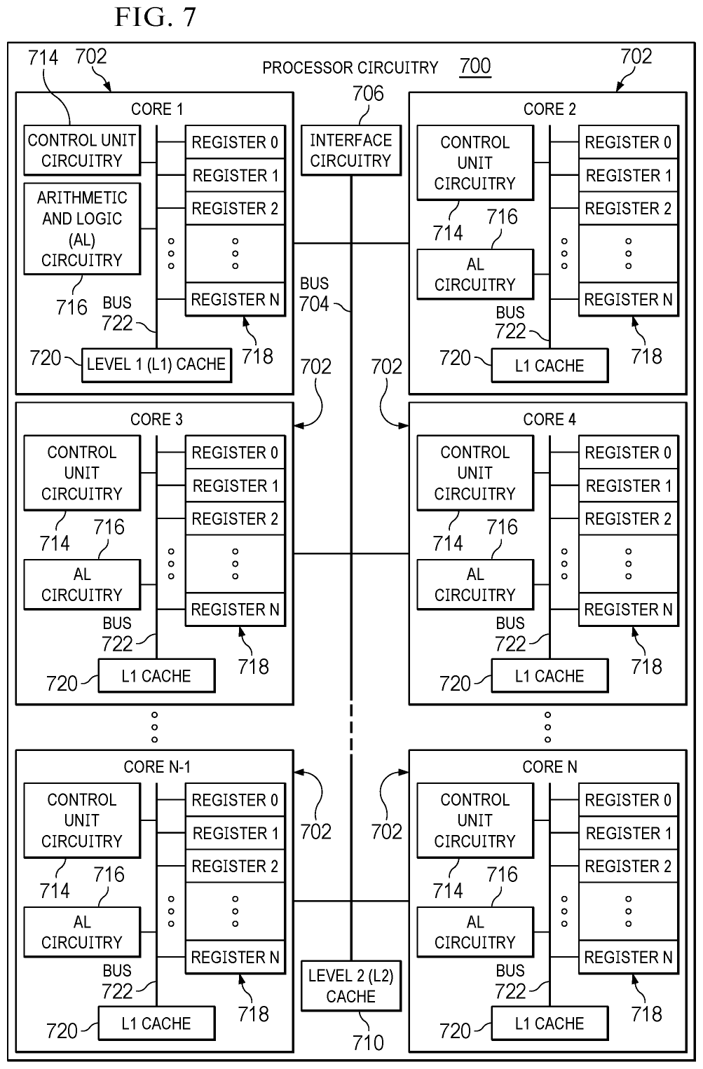

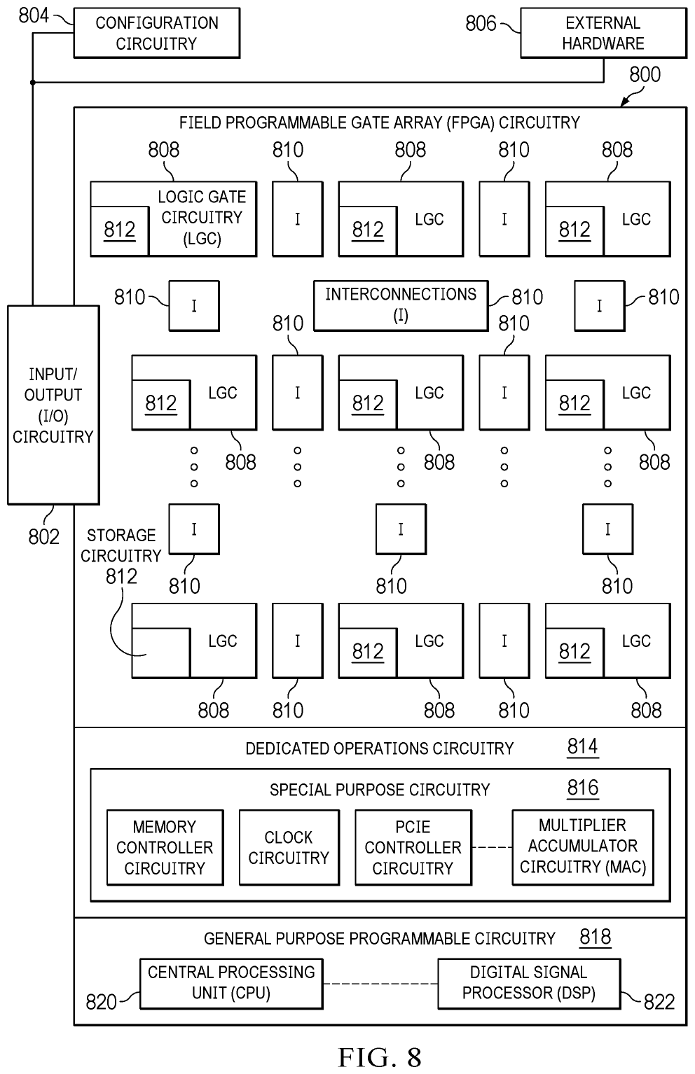

In some examples, the short detection circuitry 200 includes means for sensing current. For example, the means for sensing current may be implemented by the current sense circuitry 210. In some examples, the current sense circuitry 210 may be instantiated by programmable circuitry such as the example programmable circuitry 612 of FIG. 6. For instance, the current sense circuitry 210 may be instantiated by the example microprocessor 700 of FIG. 7 executing machine executable instructions such as those implemented by at least block 405 of FIG. 4. In some examples, the current sense circuitry 210 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the current sense circuitry 210 may be instantiated by any other combination of hardware, software, and/or firmware. For example, the current sense circuitry 210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for multiplexing. For example, the means for multiplexing may be implemented by the multiplexer circuitry 215. In some examples, the multiplexer circuitry 215 may be instantiated by programmable circuitry such as the example programmable circuitry 612 of FIG. 6. For instance, the multiplexer circuitry 215 may be instantiated by the example microprocessor 700 of FIG. 7 executing machine executable instructions such as those implemented by at least block 410 of FIG. 4. In some examples, the multiplexer circuitry 215 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the multiplexer circuitry 215 may be instantiated by any other combination of hardware, software, and/or firmware. For example, the multiplexer circuitry 215 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for anti-aliasing. For example, the means for anti-aliasing may be implemented by the anti-alias filter 220. In some examples, the anti-alias filter 220 may be instantiated by programmable circuitry such as the example programmable circuitry 612 of FIG. 6. For instance, the anti-alias filter 220 may be instantiated by the example microprocessor 700 of FIG. 7 executing machine executable instructions such as those implemented by at least block 415 of FIG. 4. In some examples, the anti-alias filter 220 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the anti-alias filter 220 may be instantiated by any other combination of hardware, software, and/or firmware. For example, the anti-alias filter 220 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for analog-to-digital converting. For example, the means for analog-to-digital converting may be implemented by the ADC 225. In some examples, the ADC 225 may be instantiated by programmable circuitry such as the example programmable circuitry 612 of FIG. 6. For instance, the ADC 225 may be instantiated by the example microprocessor 700 of FIG. 7 executing machine executable instructions such as those implemented by at least block 415 of FIG. 4. In some examples, the ADC 225 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the ADC 225 may be instantiated by any other combination of hardware, software, and/or firmware. For example, the ADC 225 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for deglitching. For example, the means for analog-to-digital deglitching may be implemented by the deglitch circuitry 235. In some examples, the deglitch circuitry 235 may be instantiated by programmable circuitry such as the example programmable circuitry 612 of FIG. 6. For instance, the deglitch circuitry 235 may be instantiated by the example microprocessor 700 of FIG. 7 executing machine executable instructions such as those implemented by at least block 415 of FIG. 4. In some examples, the deglitch circuitry 235 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the deglitch circuitry 235 may be instantiated by any other combination of hardware, software, and/or firmware. For example, the deglitch circuitry 235 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for down-sampling. For example, the means for down-sampling may be implemented by the decimation circuitry 240. In some examples, the decimation circuitry 240 may be instantiated by programmable circuitry such as the example programmable circuitry 612 of FIG. 6. For instance, the decimation circuitry 240 may be instantiated by the example microprocessor 700 of FIG. 7 executing machine executable instructions such as those implemented by at least block 420 of FIG. 4. In some examples, the decimation circuitry 240 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the decimation circuitry 240 may be instantiated by any other combination of hardware, software, and/or firmware. For example, the decimation circuitry 240 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for low pass filtering. For example, the means for low pass filtering may be implemented by the low pass filter 245. In some examples, the low pass filter 245 may be instantiated by programmable circuitry such as the example programmable circuitry 612 of FIG. 6. For instance, the low pass filter 245 may be instantiated by the example microprocessor 700 of FIG. 7 executing machine executable instructions such as those implemented by at least block 425 of FIG. 4. In some examples, the low pass filter 245 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the low pass filter 245 may be instantiated by any other combination of hardware, software, and/or firmware. For example, the low pass filter 245 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for fault detecting. For example, the means for fault detecting may be implemented by the fault detection circuitry 250. In some examples, the fault detection circuitry 250 may be instantiated by programmable circuitry such as the example programmable circuitry 612 of FIG. 6. For instance, the fault detection circuitry 250 may be instantiated by the example microprocessor 700 of FIG. 7 executing machine executable instructions such as those implemented by at least blocks 430 and 435 of FIG. 4. In some examples, the fault detection circuitry 250 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the fault detection circuitry 250 may be instantiated by any other combination of hardware, software, and/or firmware. For example, the fault detection circuitry 250 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 200 includes means for fault controlling. For example, the means for controlling may be implemented by the timing circuitry 255. In some examples, the timing circuitry 255 may be instantiated by programmable circuitry such as the example programmable circuitry 612 of FIG. 6. For instance, the timing circuitry 255 may be instantiated by the example microprocessor 700 of FIG. 7 executing machine executable instructions such as those implemented by at least block 410 of FIG. 4. In some examples, the timing circuitry 255 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the timing circuitry 255 may be instantiated by any other combination of hardware, software, and/or firmware. For example, the timing circuitry 255 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the preceding description, the short detection circuitry 200 has been described in the context of detecting short circuit conditions associated with outputs of a switching amplifier, such as the amplifier 110. However, the short detection circuitry 200 is not limited to use with switching amplifiers. On the contrary, the short detection circuitry 200 can be utilized to detect short circuit conditions associated with other types of amplifier circuits.

While a first example manner of implementing the short detection circuitry 105 of FIG. 1 is illustrated in FIG. 2, one or more of the elements, processes, and/or devices illustrated in FIG. 2 may be combined, divided, re-arranged, omitted, eliminated, and/or implemented in any other way. Further, the example analog circuitry 205, the example current sense circuitry 210, the example multiplexer circuitry 215, the example anti-alias filter 220, the example ADC 225, the example digital circuitry 230, the example deglitch circuitry 235, the example decimation circuitry 240, the example low pass filter 245, the example fault detection circuitry 250, the example timing circuitry 255 and/or, more generally, the example short detection circuitry 200 of FIG. 2 may be implemented by hardware alone or by hardware in combination with software and/or firmware. Thus, for example, any of the example analog circuitry 205, the example current sense circuitry 210, the example multiplexer circuitry 215, the example anti-alias filter 220, the example ADC 225, the example digital circuitry 230, the example deglitch circuitry 235, the example decimation circuitry 240, the example low pass filter 245, the example fault detection circuitry 250, the example timing circuitry 255 and/or, more generally, the example short detection circuitry 200 could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example short detection circuitry 200 of FIG. 2 may include one or more elements, processes, and/or devices in addition to, or instead of, those illustrated in FIG. 2 and/or may include more than one of any or all of the illustrated elements, processes and devices.

FIG. 3 is a block diagram of a second example implementation 300 of the short detection circuitry 105 of FIG. 1. The short detection circuitry 300 of FIG. 3 may be instantiated (e.g., creating an instance of, bring into being for any length of time, materialize, implement, etc.) by programmable circuitry such as a Central Processor Unit (CPU) executing first instructions. Additionally or alternatively, the short detection circuitry 105 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

Unlike the short detection circuitry 200 of FIG. 2, the short detection circuitry 300 of FIG. 3 omits the multiplexer circuitry 215 and associated deglitch circuitry 235 and timing circuitry 255 and, instead, implements two processing paths to sense and evaluate the output currents at the positive output 120 and negative output 125 of the amplifier 110 continuously in parallel. For example, the short detection circuitry 300 includes first example current sense circuitry 302, a first example anti-alias filter 304, a first example ADC 306, first example decimation circuitry 308 and a first example low pass filter 310 to sense and process the output current at the positive output 120 of the amplifier 110 to determine the positive output DC bias associated with the positive amplifier output 120. The short detection circuitry 300 also includes second example current sense circuitry 312, a second example anti-alias filter 314, a second example ADC 316, second example decimation circuitry 318 and a second example low pass filter 320 to sense and process the output current at the negative output 125 of the amplifier 110 to determine the negative output DC bias associated with the negative amplifier output 120. The short detection circuitry 300 further includes example fault detection circuitry 321 detect short circuit conditions associated with the positive amplifier output 120 based on the positive output DC bias and short circuit conditions associated with the negative amplifier output 125 associated with the negative output DC bias.

The first current sense circuitry 302 of FIG. 3 has an example current sense input 322 to couple to the positive amplifier output 120 of the amplifier 110. As such, in the illustrated example, the current sense input 322 corresponds to the positive input 150 of the short detection circuitry 105. The first current sense circuitry 302 of the illustrated example is structured to sense the current applied to the current sense input 322, which corresponds to the positive output current at the positive output 120 of the amplifier 110. The first current sense circuitry 302 further has an example current sense output 324 to output the sensed current associated with current sense input 322, which corresponds to the positive output current at the positive output 120 of the amplifier 110.

The first anti-alias filter 304 of FIG. 3 has an example filter input 326 to couple to the current sense output 324 of the first current sense circuitry 302. The first anti-alias filter 304 also has an example filter output 328. The first anti-alias filter 304 of the illustrated example is structured to restrict the bandwidth of the sensed current signal output from the first current sense circuitry 302 based on the sampling rate employed by the first ADC 306 to thereby reduce or eliminate aliasing effects in the digital data produced by the first ADC 306.

The first ADC 306 of FIG. 3 has an example ADC input 330 to couple to the filter output 328 of the first anti-alias filter 304. The first ADC 306 also has an example ADC output 332. The first ADC 306 of the illustrated example is structured to convert an analog signal applied to the ADC input 330 to a digital signal produced at the ADC output 332. For example, the first ADC 306 can implement a sigma-delta ADC, an SAR ADC, etc. In the illustrated example, the analog signal applied to the ADC input 330 corresponds to the current sense output 324 of the first current sense circuitry 302, and the digital signal produced at the ADC output 332 corresponds a digital signal representative of the current sense output 324 of the first current sense circuitry 302.

The first decimation circuitry 308 of FIG. 3 has an example decimation input 334 to couple to the ADC output 332 of the first ADC 306. The first decimation circuitry 308 also has an example decimation output 336. In the illustrated example, the first decimation circuitry 308 is structured to perform decimation, or down-sampling, of an input digital signal applied to the decimation input 334 to produce a down-sampled digital signal at the decimation output 336 with a reduced sampling rate relative to the sampling rate of the input digital signal. As such, the down-sampled digital signal at the decimation output 336 corresponds to a down-sampled digital signal representative of the current sense output 324 of the first current sense circuitry 302. Inclusion of the first decimation circuitry 308 in the example short detection circuitry 300 of FIG. 3 enables downstream circuit elements of the short detection circuitry 300 (e.g., such as the low pass filter 310, etc.) to operate at a reduced sampling rate, thereby reducing the power consumption of those circuit elements. However, in some examples, the first decimation circuitry 308 is not included in the short detection circuitry 300.

The first low pass filter 310 of FIG. 3 has an example filter input 338 to couple to the decimation output 336 of the first decimation circuitry 308 The first low pass filter 310 also has an example filter output 340. In the illustrated example, the first low pass filter 310 is structured to filter the digital signal applied to the filter input 338 to generate an output value at the filter output 340 representative of the DC offset of the input digital signal. As such, the first low pass filter 310 may have a relatively low cutoff frequency, such as less than or equal to 10 Hertz (Hz) or some other suitable cutoff frequency. As the digital signal applied to the filter input 338 corresponds to the current sense output 324 of the current sense circuitry 302, the output value at the filter output 340 corresponds to the DC offset of the sensed current associated the positive output 120 of the amplifier 110, which is referred to herein as the positive output DC offset.

The second current sense circuitry 312 of FIG. 3 has an example current sense input 342 to couple to the negative amplifier output 125 of the amplifier 110. As such, in the illustrated example, the current sense input 342 corresponds to the negative input 155 of the short detection circuitry 105. The second current sense circuitry 312 of the illustrated example is structured to sense the current applied to the current sense input 342, which corresponds to the negative output current at the negative output 125 of the amplifier 110. The second current sense circuitry 312 further has an example current sense output 344 to output the sensed current associated with current sense input 342, which corresponds to the negative output current at the negative output 125 of the amplifier 110.

The second anti-alias filter 314 of FIG. 3 has an example filter input 346 to couple to the current sense output 344 of the second current sense circuitry 312. The second anti-alias filter 314 also has an example filter output 348. The second anti-alias filter 314 of the illustrated example is structured to restrict the bandwidth of the sensed current signal output from the second current sense circuitry 312 based on the sampling rate employed by the second ADC 316 to thereby reduce or eliminate aliasing effects in the digital data produced by the second ADC 316.

The second ADC 316 of FIG. 3 has an example ADC input 350 to couple to the filter output 348 of the second anti-alias filter 314. The second ADC 316 also has an example ADC output 352. The second ADC 316 of the illustrated example is structured to convert an analog signal applied to the ADC input 350 to a digital signal produced at the ADC output 352. For example, the second ADC 316 can implement a sigma-delta ADC, an SAR ADC, etc. In the illustrated example, the analog signal applied to the ADC input 350 corresponds to the current sense output 344 of the second current sense circuitry 312, and the digital signal produced at the ADC output 332 corresponds a digital signal representative of the current sense output 344 of the second current sense circuitry 312.

The second decimation circuitry 318 of FIG. 3 has an example decimation input 354 to couple to the ADC output 352 of the second ADC 316. The second decimation circuitry 318 also has an example decimation output 356. In the illustrated example, the second decimation circuitry 318 is structured to perform decimation, or down-sampling, of an input digital signal applied to the decimation input 354 to produce a down-sampled digital signal at the decimation output 356 with a reduced sampling rate relative to the sampling rate of the input digital signal. As such, the down-sampled digital signal at the decimation output 356 corresponds to a down-sampled digital signal representative of the current sense output 344 of the second current sense circuitry 312. Inclusion of the second decimation circuitry 318 in the example short detection circuitry 300 of FIG. 3 enables downstream circuit elements of the short detection circuitry 300 (e.g., such as the low pass filter 320, etc.) to operate at a reduced sampling rate, thereby reducing the power consumption of those circuit elements. However, in some examples, the second decimation circuitry 318 is not included in the short detection circuitry 300.

The second low pass filter 320 of FIG. 3 has an example filter input 358 to couple to the decimation output 356 of the second decimation circuitry 318. The second low pass filter 320 also has an example filter output 360. In the illustrated example, the second low pass filter 320 is structured to filter the digital signal applied to the filter input 358 to generate an output value at the filter output 360 representative of the DC offset of the input digital signal. As such, the second low pass filter 320 may have a relatively low cutoff frequency, such as less than or equal to 10 Hertz (Hz) or some other suitable cutoff frequency. As the digital signal applied to the filter input 358 corresponds to the current sense output 344 of the second current sense circuitry 312, the output value at the filter output 360 corresponds to the DC offset of the sensed current associated the negative output 125 of the amplifier 110, which is referred to herein as the negative output DC offset.

The example fault detection circuitry 321 of FIG. 3 has a first example detection input 362 to couple to the filter output 340 of the first low pass filter 310. The example fault detection circuitry 321 also has a second example detection input 364 to couple to the filter output 360 of the second low pass filter 320. The fault detection circuitry 321 further has an example fault output 366, which corresponds to the fault output 160 of the short detection circuitry 105 of FIG. 1. In the illustrated example, the fault detection circuitry 321 is structured to set the fault output 366 to signal detection of a short associated with at least one of the positive amplifier output 120 or the negative amplifier output 125 of the amplifier 110. The fault detection circuitry 250 is also structured to detect such a short circuit condition associated with the positive amplifier output 120 based on the positive output DC offset determined by the first low pass filter 310, and to detect such a short circuit condition associated with the negative amplifier output 125 based on the negative output DC offset determined by the second low pass filter 320.

Like the fault detection circuitry 250 of FIG. 2, the fault detection circuitry 321 of FIG. 3 may compare the input DC offsets to one or more example thresholds 368 to detect a short circuit condition associated with the positive amplifier output 120 and/or the negative amplifier output 125 of the amplifier 110. Also like the fault detection circuitry 250 of FIG. 2, the fault output 366 of the fault detection circuitry 321 of FIG. 3 includes an example fault terminal 370 and an example register 371. However, in some examples, the fault output 366 can include multiple terminals instead of, or in addition to, the fault terminal 370 and the example register 372. In the illustrated example, the fault detection circuitry 321 sets the fault terminal 370 to a first logic value to indicate a short condition has been detected, sets the fault terminal 370 to a second logic value to indicate no short condition has been detected and sets the register 372 to a value to indicate the type of short condition detected. For example, the fault detection circuitry 321 can operate to set the register 372 as follows:
(1) set the register 372 to a first value to indicate a short to power condition exists at the positive amplifier output 120;
(2) set the register 372 to a second value to indicate a short to ground condition exists at the positive amplifier output 120;
(3) set the register 372 to a third value to indicate a short to power condition exists at the negative amplifier output 125; and
(4) set the register 372 to a fourth value to indicate a short to ground condition exists at the negative amplifier output 120.

The other implementation and operation details of the fault detection circuitry 321 are similar or identical to those of the fault detection circuitry 250 of FIG. 2. Accordingly, those details are described above in connection with FIG. 2.

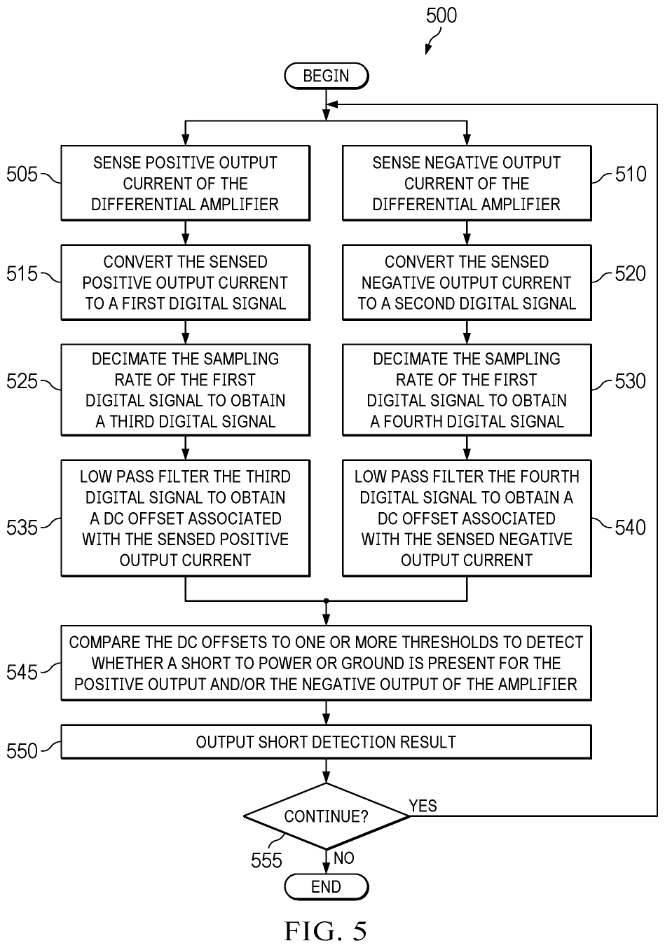

In some examples, the short detection circuitry 300 includes means for sensing current. For example, the means for sensing current may be implemented by the first current sense circuitry 302 and/or the second current sense circuitry 312. In some examples, the first current sense circuitry 302 and/or the second current sense circuitry 312 may be instantiated by programmable circuitry such as the example programmable circuitry 612 of FIG. 6. For instance, the first current sense circuitry 302 and/or the second current sense circuitry 312 may be instantiated by the example microprocessor 700 of FIG. 7 executing machine executable instructions such as those implemented by at least blocks 505 and 510 of FIG. 5. In some examples, the first current sense circuitry 302 and/or the second current sense circuitry 312 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the first current sense circuitry 302 and/or the second current sense circuitry 312 may be instantiated by any other combination of hardware, software, and/or firmware. For example, the first current sense circuitry 302 and/or the second current sense circuitry 312 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 300 includes means for anti-aliasing. For example, the means for anti-aliasing may be implemented by the first anti-alias filter 304 and/or the second anti-alias filter 314. In some examples, the first anti-alias filter 304 and/or the second anti-alias filter 314 may be instantiated by programmable circuitry such as the example programmable circuitry 612 of FIG. 6. For instance, the first anti-alias filter 304 and/or the second anti-alias filter 314 may be instantiated by the example microprocessor 700 of FIG. 7 executing machine executable instructions such as those implemented by at least blocks 515 and/or 520 of FIG. 5. In some examples, the first anti-alias filter 304 and/or the second anti-alias filter 314 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the first anti-alias filter 304 and/or the second anti-alias filter 314 may be instantiated by any other combination of hardware, software, and/or firmware. For example, the first anti-alias filter 304 and/or the second anti-alias filter 314 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 300 includes means for analog-to-digital converting. For example, the means for analog-to-digital converting may be implemented by the first ADC 306 and/or the second ADC 316. In some examples, the first ADC 306 and/or the second ADC 316 may be instantiated by programmable circuitry such as the example programmable circuitry 612 of FIG. 6. For instance, the first ADC 306 and/or the second ADC 316 may be instantiated by the example microprocessor 700 of FIG. 7 executing machine executable instructions such as those implemented by at least blocks 515 and/or 520 of FIG. 5. In some examples, the first ADC 306 and/or the second ADC 316 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the first ADC 306 and/or the second ADC 316 may be instantiated by any other combination of hardware, software, and/or firmware. For example, the first ADC 306 and/or the second ADC 316 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 300 includes means for down-sampling. For example, the means for down-sampling may be implemented by the first decimation circuitry 308 and/or the second decimation circuitry 318. In some examples, the first decimation circuitry 308 and/or the second decimation circuitry 318 may be instantiated by programmable circuitry such as the example programmable circuitry 612 of FIG. 6. For instance, the first decimation circuitry 308 and/or the second decimation circuitry 318 may be instantiated by the example microprocessor 700 of FIG. 7 executing machine executable instructions such as those implemented by at least blocks 525 and/or 530 of FIG. 5. In some examples, the first decimation circuitry 308 and/or the second decimation circuitry 318 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the first decimation circuitry 308 and/or the second decimation circuitry 318 may be instantiated by any other combination of hardware, software, and/or firmware. For example, the first decimation circuitry 308 and/or the second decimation circuitry 318 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 300 includes means for low pass filtering. For example, the means for low pass filtering may be implemented by the first low pass filter 310 and/or the second low pass filter 320. In some examples, the first low pass filter 310 and/or the second low pass filter 320 may be instantiated by programmable circuitry such as the example programmable circuitry 612 of FIG. 6. For instance, the first low pass filter 310 and/or the second low pass filter 320 may be instantiated by the example microprocessor 700 of FIG. 7 executing machine executable instructions such as those implemented by at least blocks 535 and/or 540 of FIG. 5. In some examples, the first low pass filter 310 and/or the second low pass filter 320 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the first low pass filter 310 and/or the second low pass filter 320 may be instantiated by any other combination of hardware, software, and/or firmware. For example, the first low pass filter 310 and/or the second low pass filter 320 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the short detection circuitry 300 includes means for fault detecting. For example, the means for fault detecting may be implemented by the fault detection circuitry 321. In some examples, the fault detection circuitry 321 may be instantiated by programmable circuitry such as the example programmable circuitry 612 of FIG. 6. For instance, the fault detection circuitry 321 may be instantiated by the example microprocessor 700 of FIG. 7 executing machine executable instructions such as those implemented by at least blocks 545 and 550 of FIG. 5. In some examples, the fault detection circuitry 321 may be instantiated by hardware logic circuitry, which may be implemented by an ASIC, XPU, or the FPGA circuitry 800 of FIG. 8 configured and/or structured to perform operations corresponding to the machine-readable instructions. Additionally, or alternatively, the fault detection circuitry 321 may be instantiated by any other combination of hardware, software, and/or firmware. For example, the fault detection circuitry 321 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the preceding description, the short detection circuitry 300 has been described in the context of detecting short circuit conditions associated with outputs of a switching amplifier, such as the amplifier 110. However, the short detection circuitry 300 is not limited to use with switching amplifiers. On the contrary, the short detection circuitry 300 can be utilized to detect short circuit conditions associated with other types of amplifier circuits.

While a second example manner of implementing the short detection circuitry 105 of FIG. 1 is illustrated in FIG. 3, one or more of the elements, processes, and/or devices illustrated in FIG. 3 may be combined, divided, re-arranged, omitted, eliminated, and/or implemented in any other way. Further, the first example current sense circuitry 302, the first example anti-alias filter 304, the first example ADC 306, the first example decimation circuitry 308, the first example low pass filter 310, the second example current sense circuitry 312, the second example anti-alias filter 314, the second example ADC 316, the second example decimation circuitry 318, the second example low pass filter 320, the example fault detection circuitry 321 and/or, more generally, the example short detection circuitry 300 of FIG. 3 may be implemented by hardware alone or by hardware in combination with software and/or firmware. Thus, for example, any of the first example current sense circuitry 302, the first example anti-alias filter 304, the first example ADC 306, the first example decimation circuitry 308, the first example low pass filter 310, the second example current sense circuitry 312, the second example anti-alias filter 314, the second example ADC 316, the second example decimation circuitry 318, the second example low pass filter 320, the example fault detection circuitry 321 and/or, more generally, the example short detection circuitry 300 could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example short detection circuitry 300 of FIG. 3 may include one or more elements, processes, and/or devices in addition to, or instead of, those illustrated in FIG. 3 and/or may include more than one of any or all of the illustrated elements, processes and devices.

A flowchart representative of example machine readable instructions, which may be executed by programmable circuitry to implement and/or instantiate the short detection circuitry 200 of FIG. 2 and/or representative of example operations which may be performed by programmable circuitry to implement and/or instantiate the short detection circuitry 300 of FIG. 2 is shown in FIG. 4. The machine readable instructions may be one or more executable programs or portion(s) of one or more executable programs for execution by programmable circuitry such as the programmable circuitry 612 shown in the example processor platform 600 discussed below in connection with FIG. 6 and/or may be one or more function(s) or portion(s) of functions to be performed by the example programmable circuitry (e.g., an FPGA) discussed below in connection with FIGS. 7 and/or 8. In some examples, the machine readable instructions cause an operation, a task, etc., to be carried out and/or performed in an automated manner in the real world. As used herein, “automated” means without human involvement.

A flowchart representative of example machine readable instructions, which may be executed by programmable circuitry to implement and/or instantiate the short detection circuitry 300 of FIG. 3 and/or representative of example operations which may be performed by programmable circuitry to implement and/or instantiate the short detection circuitry 300 of FIG. 3 is shown in FIG. 5. The machine readable instructions may be one or more executable programs or portion(s) of one or more executable programs for execution by programmable circuitry such as the programmable circuitry 612 shown in the example processor platform 600 discussed below in connection with FIG. 6 and/or may be one or more function(s) or portion(s) of functions to be performed by the example programmable circuitry (e.g., an FPGA) discussed below in connection with FIGS. 7 and/or 8. In some examples, the machine readable instructions cause an operation, a task, etc., to be carried out and/or performed in an automated manner in the real world. As used herein, “automated” means without human involvement.

The programs may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, nonvolatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example programs are described with reference to the flowchart(s) illustrated in FIGS. 4-5, many other methods of implementing the example short detection circuitry 200 and/or the example short detection circuitry 300 may alternatively be used. For example, the order of execution of the blocks of the flowchart(s) may be changed, and/or some of the blocks described may be changed, eliminated, or combined. Additionally, or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine readable, computer readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 4-5 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine-readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C. (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 4 is a flowchart representative of example machine readable instructions and/or example operations 400 that may be executed, instantiated, and/or performed by programmable circuitry to implement the short detection circuitry 200 of FIG. 2. With reference to the preceding figures and corresponding written descriptions, the example machine-readable instructions and/or the example operations 400 of FIG. 4 begin at block 405 at which the current sense circuitry 210 senses the current at the positive output 120 of the amplifier 110 and senses the current at the negative output 125 of the amplifier 110, as described above. At block 410, the timing circuitry 255 repeatedly switches the multiplexer circuitry 215 to alternate between selection of the sensed current at the positive amplifier output 120 and selection of the sensed current at the negative amplifier output 125, as described above. At block 415, the ADC 225, in combination with the anti-alias filter 220 and the deglitch circuitry 235, converts the sensed output current selected at block 410 to a first digital signal, as described above. At block 420, the decimation circuitry 240 down-samples or, in other words, decimates the sampling rate of the first digital signal to obtain a second digital signal, as described above. In some examples, the processing at block 420 is optional and can be omitted.

At block 425, the low pass filter 245 filters the second digital signal to obtain a DC offset associated with the sensed output current selected at block 410, as described above. At block 430, the fault detection circuitry 250 compares the DC offset to one or more thresholds to detect, as described above, whether a short to power or ground is present for the amplifier output associated with the sensed output current selected at block 410. At block 435, the fault detection circuitry 250 sets the fault output 295 to indicate whether a short circuit condition has been detected, as described above. At block 440, if short circuit detection is to continue, processing returns to block 405 and the blocks subsequent thereto. Otherwise, the example machine-readable instructions and/or the example operations 400 end.

FIG. 5 is a flowchart representative of example machine readable instructions and/or example operations 500 that may be executed, instantiated, and/or performed by programmable circuitry to implement the short detection circuitry 300 of FIG. 3. With reference to the preceding figures and corresponding written descriptions, the example machine-readable instructions and/or the example operations 500 of FIG. 5 begin at block 505 and block 510 in parallel. At block 505, the first current sense circuitry 302 senses the current at the positive output 120 of the amplifier 110, as described above. In parallel, at block 510, the second current sense circuitry 312 senses the current at the negative output 125 of the amplifier 110, as described above.

Next, at block 515, the first ADC 306, in combination with the first anti-alias filter 304, converts the sensed current at the positive amplifier output 120 to a first digital signal, as described above. In parallel, at block 520, the second ADC 316, in combination with the second anti-alias filter 314, converts the sensed current at the negative amplifier output 125 to a second digital signal, as described above.

Next, at block 525, the first decimation circuitry 308 down-samples the sampling rate of the first digital signal to obtain a third digital signal, as described above. In parallel, at block 530, the second decimation circuitry 318 down-samples the sampling rate of the second digital signal to obtain a fourth digital signal, as described above. In some examples, the processing at blocks 525 and 530 is optional and can be omitted.

Next, at block 535, the first low pass filter 310 filters the third digital signal to obtain, as described above, a DC offset associated with the positive amplifier output 120, which is referred to as the positive output DC offset. In parallel, at block 540, the second low pass filter 320 filters the fourth digital signal to obtain, as described above, a DC offset associated with the negative amplifier output 125, which is referred to as the negative output DC offset.

At block 545, the fault detection circuitry 321 compares the positive output DC offset and the negative output DC offset to one or more thresholds to detect, as described above, whether a short to power or ground is present for the positive amplifier output 120 and/or the negative amplifier output 120. At block 550, the fault detection circuitry 321 sets the fault output 366 to indicate whether a short circuit condition has been detected, as described above. At block 555, if short circuit detection is to continue, processing returns to blocks 505 and 510, and the blocks subsequent thereto. Otherwise, the example machine-readable instructions and/or the example operations 500 end.

FIG. 6 is a block diagram of an example programmable circuitry platform 600 structured to execute and/or instantiate the example machine-readable instructions and/or the example operations of FIGS. 4 and/or 5 to implement the short detection circuitry 200 and/or short detection circuitry 300 of FIGS. 2 and/or 3. The programmable circuitry platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, FPGAs, microprocessors, CPUs, GPUs, DSPs, and/or microcontrollers from any desired family or manufacturer. The programmable circuitry 612 may be implemented by one or more semiconductor based (e.g., silicon based) devices. In some examples, the programmable circuitry 612 implements the example deglitch circuitry 235, the example decimation circuitry 240, the example low pass filter 245, the example fault detection circuitry 250 and the example timing circuitry 255 of the short detection circuitry 200. In some examples, the programmable circuitry 612 implements the first example decimation circuitry 308, the first example low pass filter 310, the second example decimation circuitry 318, the second example low pass filter 320 and the example fault detection circuitry 321 of the short detection circuitry 300.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 616 may be implemented by flash memory and/or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. In some examples, the interface circuitry 620 implements the example current sense circuitry 210, the example multiplexer circuitry 215, the example anti-alias filter 220 and the example ADC 225 of the short detection circuitry 200. In some examples, the interface circuitry 620 implements the first example current sense circuitry 302, the first example anti-alias filter 304, the first example ADC 306, the second example current sense circuitry 312, the second example anti-alias filter 314, and the second example ADC 316 of the short detection circuitry 300.

In the illustrated example, one or more input devices 622 are connected to the interface circuitry 620. The input device(s) 622 permit(s) a user (e.g., a human user, a machine user, etc.) to enter data and/or commands into the programmable circuitry 612. The input device(s) 622 can be implemented by, for example, an audio sensor, a microphone, a camera (still or video), a keyboard, a button, a mouse, a touchscreen, a trackpad, a trackball, an isopoint device, and/or a voice recognition system.

One or more output devices 624 are also connected to the interface circuitry 620 of the illustrated example. The output device(s) 624 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 620 of the illustrated example, thus, typically includes a graphics driver card, a graphics driver chip, and/or graphics processor circuitry such as a GPU.

The interface circuitry 620 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store firmware, software, and/or data. Examples of such mass storage discs or devices 628 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 632, which may be implemented by the machine readable instructions of FIGS. 4 and/or 5, may be stored in the mass storage device 628, in the volatile memory 614, in the non-volatile memory 616, and/or on at least one non-transitory computer readable storage medium such as a CD or DVD which may be removable.

FIG. 7 is a block diagram of an example implementation of the programmable circuitry 612 of FIG. 6. In this example, the programmable circuitry 612 of FIG. 6 is implemented by a microprocessor 700. For example, the microprocessor 700 may be a general-purpose microprocessor (e.g., general-purpose microprocessor circuitry). The microprocessor 700 executes some or all of the machine-readable instructions of the flowcharts of FIGS. 4 and/or 5 to effectively instantiate the circuitry of FIGS. 2 and/or 3 as logic circuits to perform operations corresponding to those machine-readable instructions. In some such examples, the circuitry of FIGS. 2 and/or 3 is instantiated by the hardware circuits of the microprocessor 700 in combination with the machine-readable instructions. For example, the microprocessor 700 may be implemented by multi-core hardware circuitry such as a CPU, a DSP, a GPU, an XPU, etc. Although it may include any number of example cores 702 (e.g., 1 core), the microprocessor 700 of this example is a multi-core semiconductor device including N cores. The cores 702 of the microprocessor 700 may operate independently or may cooperate to execute machine readable instructions. For example, machine code corresponding to a firmware program, an embedded software program, or a software program may be executed by one of the cores 702 or may be executed by multiple ones of the cores 702 at the same or different times. In some examples, the machine code corresponding to the firmware program, the embedded software program, or the software program is split into threads and executed in parallel by two or more of the cores 702. The software program may correspond to a portion or all of the machine-readable instructions and/or operations represented by the flowcharts of FIGS. 4 and/or 5.

The cores 702 may communicate by a first example bus 704. In some examples, the first bus 704 may be implemented by a communication bus to effectuate communication associated with one(s) of the cores 702. For example, the first bus 704 may be implemented by at least one of an Inter-Integrated Circuit (I2C) bus, a Serial Peripheral Interface (SPI) bus, a PCI bus, or a PCIe bus. Additionally or alternatively, the first bus 704 may be implemented by any other type of computing or electrical bus. The cores 702 may obtain data, instructions, and/or signals from one or more external devices by example interface circuitry 706. The cores 702 may output data, instructions, and/or signals to the one or more external devices by the interface circuitry 706. Although the cores 702 of this example include example local memory 720 (e.g., Level 1 (L1) cache that may be split into an L1 data cache and an L1 instruction cache), the microprocessor 700 also includes example shared memory 710 that may be shared by the cores (e.g., Level 2 (L2 cache)) for high-speed access to data and/or instructions. Data and/or instructions may be transferred (e.g., shared) by writing to and/or reading from the shared memory 710. The local memory 720 of each of the cores 702 and the shared memory 710 may be part of a hierarchy of storage devices including multiple levels of cache memory and the main memory (e.g., the main memory 614, 616 of FIG. 6). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 702 may be referred to as a CPU, DSP, GPU, etc., or any other type of hardware circuitry. Each core 702 includes control unit circuitry 714, arithmetic and logic (AL) circuitry (sometimes referred to as an ALU) 716, a plurality of registers 718, the local memory 720, and a second example bus 722. Other structures may be present. For example, each core 702 may include vector unit circuitry, single instruction multiple data (SIMD) unit circuitry, load/store unit (LSU) circuitry, branch/jump unit circuitry, floating-point unit (FPU) circuitry, etc. The control unit circuitry 714 includes semiconductor-based circuits structured to control (e.g., coordinate) data movement within the corresponding core 702. The AL circuitry 716 includes semiconductor-based circuits structured to perform one or more mathematic and/or logic operations on the data within the corresponding core 702. The AL circuitry 716 of some examples performs integer-based operations. In other examples, the AL circuitry 716 also performs floating-point operations. In yet other examples, the AL circuitry 716 may include first AL circuitry that performs integer-based operations and second AL circuitry that performs floating-point operations. In some examples, the AL circuitry 716 may be referred to as an Arithmetic Logic Unit (ALU).

The registers 718 are semiconductor-based structures to store data and/or instructions such as results of one or more of the operations performed by the AL circuitry 716 of the corresponding core 702. For example, the registers 718 may include vector register(s), SIMD register(s), general-purpose register(s), flag register(s), segment register(s), machine-specific register(s), instruction pointer register(s), control register(s), debug register(s), memory management register(s), machine check register(s), etc. The registers 718 may be arranged in a bank as shown in FIG. 7. Alternatively, the registers 718 may be organized in any other arrangement, format, or structure, such as by being distributed throughout the core 702 to shorten access time. The second bus 722 may be implemented by at least one of an I2C bus, a SPI bus, a PCI bus, or a PCIe bus.

Each core 702 and/or, more generally, the microprocessor 700 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 700 is a semiconductor device fabricated to include many transistors interconnected to implement the structures described above in one or more integrated circuits (ICs) contained in one or more packages.

The microprocessor 700 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 700, in the same chip package as the microprocessor 700 and/or in one or more separate packages from the microprocessor 700.

FIG. 8 is a block diagram of another example implementation of the programmable circuitry 612 of FIG. 6. In this example, the programmable circuitry 612 is implemented by FPGA circuitry 800. For example, the FPGA circuitry 800 may be implemented by an FPGA. The FPGA circuitry 800 can be used, for example, to perform operations that could otherwise be performed by the example microprocessor 700 of FIG. 7 executing corresponding machine-readable instructions. However, once configured, the FPGA circuitry 800 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 700 of FIG. 7 described above (which is a general purpose device that may be programmed to execute some or all of the machine readable instructions represented by the flowchart(s) of FIGS. 4 and/or 5 but whose interconnections and logic circuitry are fixed once fabricated), the FPGA circuitry 800 of the example of FIG. 8 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 4 and/or 5. In particular, the FPGA circuitry 800 may be thought of as an array of logic gates, interconnections, and switches. The switches can be programmed to change how the logic gates are interconnected by the interconnections, effectively forming one or more dedicated logic circuits (unless and until the FPGA circuitry 800 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 4 and/or 5. As such, the FPGA circuitry 800 may be configured and/or structured to effectively instantiate some or all of the operations/functions corresponding to the machine readable instructions of the flowchart(s) of FIGS. 4 and/or 5 as dedicated logic circuits to perform the operations/functions corresponding to those software instructions in a dedicated manner analogous to an ASIC. Therefore, the FPGA circuitry 800 may perform the operations/functions corresponding to the some or all of the machine-readable instructions of FIGS. 4 and/or 5 faster than the general-purpose microprocessor can execute the same.

In the example of FIG. 8, the FPGA circuitry 800 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

The FPGA circuitry 800 of FIG. 8, includes example input/output (I/O) circuitry 802 to obtain and/or output data to/from example configuration circuitry 804 and/or external hardware 806. For example, the configuration circuitry 804 may be implemented by interface circuitry that may obtain a binary file, which may be implemented by a bit stream, data, and/or machine-readable instructions, to configure the FPGA circuitry 800, or portion(s) thereof. In some such examples, the configuration circuitry 804 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 806 may be implemented by external hardware circuitry. For example, the external hardware 806 may be implemented by the microprocessor 700 of FIG. 7.

The FPGA circuitry 800 also includes an array of example logic gate circuitry 808, a plurality of example configurable interconnections 810, and example storage circuitry 812. The logic gate circuitry 808 and the configurable interconnections 810 are configurable to instantiate one or more operations/functions that may correspond to at least some of the machine-readable instructions of FIGS. 4 and/or 5 and/or other desired operations. The logic gate circuitry 808 shown in FIG. 8 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 808 to enable configuration of the electrical structures and/or the logic gates to form circuits to perform desired operations/functions. The logic gate circuitry 808 may include other electrical structures such as look-up tables (LUTs), registers (e.g., flip-flops or latches), multiplexers, etc.

The configurable interconnections 810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 808 to program desired logic circuits.

The storage circuitry 812 of the illustrated example is structured to store result(s) of the one or more of the operations performed by corresponding logic gates. The storage circuitry 812 may be implemented by registers or the like. In the illustrated example, the storage circuitry 812 is distributed amongst the logic gate circuitry 808 to facilitate access and increase execution speed.

The example FPGA circuitry 800 of FIG. 8 also includes example dedicated operations circuitry 814. In this example, the dedicated operations circuitry 814 includes special purpose circuitry 816 that may be invoked to implement commonly used functions to avoid the need to program those functions in the field. Examples of such special purpose circuitry 816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 800 may also include example general purpose programmable circuitry 818 such as an example CPU 820 and/or an example DSP 822. Other general-purpose programmable circuitry 818 may additionally or alternatively be present such as a GPU, an XPU, etc., that can be programmed to perform other operations.

Although FIGS. 7 and 8 illustrate two example implementations of the programmable circuitry 612 of FIG. 6, many other approaches are contemplated. For example, FPGA circuitry may include an on-board CPU, such as one or more of the example CPU 820 of FIG. 7. Therefore, the programmable circuitry 612 of FIG. 6 may additionally be implemented by combining at least the example microprocessor 700 of FIG. 7 and the example FPGA circuitry 800 of FIG. 8. In some such hybrid examples, one or more cores 702 of FIG. 7 may execute a first portion of the machine readable instructions represented by the flowchart(s) of FIGS. 4 and/or 5 to perform first operation(s)/function(s), the FPGA circuitry 800 of FIG. 8 may be configured and/or structured to perform second operation(s)/function(s) corresponding to a second portion of the machine readable instructions represented by the flowcharts of FIG. 4 and/or 5, and/or an ASIC may be configured and/or structured to perform third operation(s)/function(s) corresponding to a third portion of the machine readable instructions represented by the flowcharts of FIGS. 4 and/or 5.

It should be understood that some or all of the circuitry of FIGS. 2 and/or 3 may, thus, be instantiated at the same or different times. For example, same and/or different portion(s) of the microprocessor 700 of FIG. 7 may be programmed to execute portion(s) of machine-readable instructions at the same and/or different times. In some examples, same and/or different portion(s) of the FPGA circuitry 800 of FIG. 8 may be configured and/or structured to perform operations/functions corresponding to portion(s) of machine-readable instructions at the same and/or different times.

In some examples, some or all of the circuitry of FIGS. 2 and/or 3 may be instantiated, for example, in one or more threads executing concurrently and/or in series. For example, the microprocessor 700 of FIG. 7 may execute machine readable instructions in one or more threads executing concurrently and/or in series. In some examples, the FPGA circuitry 800 of FIG. 8 may be configured and/or structured to carry out operations/functions concurrently and/or in series. Moreover, in some examples, some or all of the circuitry of FIGS. 2 and/or 3 may be implemented within one or more virtual machines and/or containers executing on the microprocessor 700 of FIG. 7.

In some examples, the programmable circuitry 612 of FIG. 6 may be in one or more packages. For example, the microprocessor 700 of FIG. 7 and/or the FPGA circuitry 800 of FIG. 8 may be in one or more packages. In some examples, an XPU may be implemented by the programmable circuitry 612 of FIG. 6, which may be in one or more packages. For example, the XPU may include a CPU (e.g., the microprocessor 700 of FIG. 7, the CPU 820 of FIG. 8, etc.) in one package, a DSP (e.g., the DSP 822 of FIG. 8) in another package, a GPU in yet another package, and an FPGA (e.g., the FPGA circuitry 800 of FIG. 8) in still yet another package.

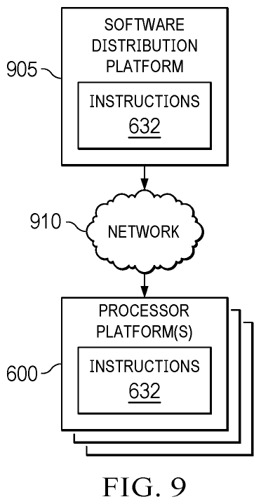

A block diagram illustrating an example software distribution platform 905 to distribute software such as the example machine readable instructions 632 of FIG. 6 to other hardware devices (e.g., hardware devices owned and/or operated by third parties from the owner and/or operator of the software distribution platform) is illustrated in FIG. 9. The example software distribution platform 905 may be implemented by any computer server, data facility, cloud service, etc., capable of storing and transmitting software to other computing devices. The third parties may be customers of the entity owning and/or operating the software distribution platform 905. For example, the entity that owns and/or operates the software distribution platform 905 may be a developer, a seller, and/or a licensor of software such as the example machine readable instructions 632 of FIG. 6. The third parties may be consumers, users, retailers, OEMs, etc., who purchase and/or license the software for use and/or re-sale and/or sub-licensing. In the illustrated example, the software distribution platform 905 includes one or more servers and one or more storage devices. The storage devices store the machine-readable instructions 632, which may correspond to the example machine readable instructions of FIGS. 4 and/or 5, as described above. The one or more servers of the example software distribution platform 905 are in communication with an example network 910, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third-party payment entity. The servers enable purchasers and/or licensors to download the machine-readable instructions 632 from the software distribution platform 905. For example, the software, which may correspond to the example machine readable instructions of FIG. 4 and/or 5, may be downloaded to the example programmable circuitry platform 600, which is to execute the machine-readable instructions 632 to implement the short detection circuitry 200 and/or short detection circuitry 300. In some examples, one or more servers of the software distribution platform 905 periodically offer, transmit, and/or force updates to the software (e.g., the example machine readable instructions 632 of FIG. 6) to ensure improvements, patches, updates, etc., are distributed and applied to the software at the end user devices. Although referred to as software above, the distributed “software” could alternatively be firmware.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for case of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that implement and utilize short detection circuitry to provide short to power and ground diagnostics for amplifier circuits. Disclosed systems, apparatus, articles of manufacture, and methods improve the efficiency of using a computing device by monitoring the outputs of a switching amplifier to detect short conditions during system operation (e.g., in real-time) and generating one or more fault diagnostics to enable identification of the short condition and/or shut-down of the amplifier and/or other system components to prevent, reduce or otherwise mitigate damage to the amplifier and/or other system components. Disclosed systems, apparatus, articles of manufacture, and methods are accordingly directed to one or more improvement(s) in the operation of a machine such as a computer or other electronic and/or mechanical device.

Further example systems, apparatus, articles of manufacture, methods and combinations thereof to implement and utilize short detection circuitry to provide short to power and ground diagnostics for amplifier circuits include the following. Example 1 includes a circuit comprising short detection circuitry having an input adapted to be coupled to an output of an amplifier, and an output, to sense an output current from the output of the amplifier, and filter a signal corresponding to the output current from the output of the amplifier to measure a direct current (DC) offset associated with the output current, wherein the short detection circuitry output indicates a short at the output of the amplifier based on the DC offset.

Example 2 includes the circuit of example 1, wherein the short detection circuitry is to set a value of the short detection circuitry output based on comparison of the DC offset to a threshold.

Example 3 includes the circuit of example 2, wherein the threshold is programmable based on a type of the amplifier.

Example 4 includes the circuit of example 2, wherein the short detection circuitry output includes a terminal, and the short detection circuitry is set a value of the terminal to indicate the short in response to a magnitude of the DC offset satisfying the threshold.

Example 5 includes the circuit of example 4, wherein amplifier is a switching amplifier, the short detection circuitry output includes a register, and the short detection circuitry is to set a value of the register based on a polarity of the DC offset to indicate whether the short is from the output of the amplifier to power or ground.

Example 6 includes the circuit of example 1, wherein the amplifier is a switching amplifier, the output of the amplifier is a positive output of the amplifier, the short detection circuitry input is a first short detection circuitry input adapted to be coupled to the positive output of the switching amplifier, the output current is a first output current associated with the positive output of the switching amplifier, the signal is a first signal corresponding to the first output current, the DC offset is a first DC offset associated with the first output current, and further including a second short detection circuitry input adapted to be coupled to a negative output of the switching amplifier, wherein the short detection circuitry is to sense a second output current from the negative output of the switching amplifier, filter a second signal corresponding to the second output current to measure a second DC offset associated with the second output current, and set the short detection circuitry output based on comparison of the first DC offset to a threshold and comparison of the second DC offset to the threshold.

Example 7 includes the circuit of example 6, wherein the short detection circuitry output includes a terminal and a register, and the short detection circuitry is to set a value of the terminal to indicate the short in response to at least one of a magnitude of the first DC offset satisfying the threshold or a magnitude of the second DC offset satisfying the threshold, set the register to a first register value to indicate the short is between the positive output of the amplifier and power in response to a polarity of the first DC offset being negative, set the register to a second register value to indicate the short is between the positive output of the amplifier and ground in response to the polarity of the first DC offset being positive, set the register to a third register value to indicate the short is between the negative output of the amplifier and power in response to a polarity of the second DC offset being positive, and set the register to a fourth register value to indicate the short is between the negative output of the amplifier and ground in response to the polarity of the second DC offset being negative.

Example 8 includes the circuit of example 6, wherein the short detection circuitry is to repeatedly switch between (i) sensing the first output current from the positive output of the switching amplifier, filtering the first signal corresponding to the first output current to measure the first DC offset, and setting the short detection circuitry output based on the comparison of the first DC offset to the threshold, and (ii) sensing the second output current from the negative output of the switching amplifier, filtering the second signal corresponding to the second output current to measure the second DC offset, and setting the short detection circuitry output based on the comparison of the second DC offset to the threshold.

Example 9 includes a switching amplifier comprising a positive amplifier output, a negative amplifier output, and short detection circuitry including current sense circuitry having a first current sense input, a first current sense output, a second current sense input, and a second current sense output, multiplexer circuitry having a first multiplexer input to couple to the first current sense output, a second multiplexer input to couple to the second current sense output, and a multiplexer output, filter circuitry to filter a signal generated on the multiplexer output to measure a direct current (DC) offset associated with the multiplexer output, and fault detection circuitry having a fault output to indicate a short on at least one of the positive amplifier output or the negative amplifier output, wherein the fault detection circuitry determines the fault output based on the DC offset.

Example 10 includes the switching amplifier of example 9, further including timing circuitry to synchronize operation of the multiplexer circuitry and the fault detection circuitry to cause the fault output to correspond to the positive amplifier output when the multiplexer output is connected to the first multiplexer input and correspond to the negative amplifier output when the multiplexer output is connected to the second multiplexer input.

Example 11 includes the switching amplifier of example 9, wherein the signal is an analog signal and further including an analog-to-digital converter to convert the analog signal to a first digital signal, and decimation circuitry to down-sample a sampling rate of the first digital signal to generate a second digital signal, wherein the filter circuitry is to filter the second digital signal to measure the DC offset.

Example 12 includes the switching amplifier of example 9, wherein the fault detection circuitry is to set a value of the fault output based on comparison of the DC offset to a threshold.

Example 13 includes the switching amplifier of example 12, wherein the threshold is a first programmable threshold that is programmable based on a type of the switching amplifier, and the fault detection circuitry is to set the value of the fault output based on comparison of the DC offset to the first programmable threshold and a second programmable threshold, wherein the second programmable threshold is programmable based on the type of the switching amplifier.

Example 14 includes the switching amplifier of example 9, wherein the fault output includes at least one of a register or a plurality of terminals, and the fault detection circuitry is to set the at least one of the register or the plurality of terminals to a first value to indicate the short is between the positive amplifier output and power, set the at least one of the register or the plurality of terminals to a second value to indicate the short is between the positive amplifier output and ground, set the at least one of the register or the plurality of terminals to a third value to indicate the short is between the negative amplifier output and power, and set the at least one of the register or the plurality of terminals to a fourth value to indicate the short is between the positive amplifier output and ground.

Example 15 includes a switching amplifier comprising short detection circuitry including first current sense circuitry having a first current sense input and a first current sense output, the first current sense input coupled to a positive amplifier output, the first current sense output to output a first sensed current associated with the positive amplifier output, second current sense circuitry having a second current sense input and a second current sense output, the second current sense input coupled to a negative amplifier output, the second current sense output to output a second sensed current associated with the negative amplifier output, first filter circuitry to filter a first signal generated on the first current sense output to measure a first direct current (DC) offset associated with the first sensed current, second filter circuitry to filter a second signal generated on the second current sense output to measure a second DC offset associated with the second sensed current, and fault detection circuitry having a fault output to indicate detection of a short on at least one of the positive amplifier output or the negative amplifier output, wherein the fault detection circuitry determines the fault output based on the first DC offset and the second DC offset.

Example 16 includes the switching amplifier of example 15, wherein the first signal is a first analog signal, the second signal is a second analog signal, and further including a first analog-to-digital converter to convert the first analog signal to a first digital signal, a second analog-to-digital converter to convert the second analog signal to a second digital signal, first decimation circuitry to down-sample a sampling rate of the first digital signal to generate a third digital signal, wherein the first filter circuitry is to filter the third digital signal to measure the first DC offset, and second decimation circuitry to down-sample a sampling rate of the second digital signal to generate a fourth digital signal, wherein the second filter circuitry is to filter the fourth digital signal to measure the second DC offset.

Example 17 includes the switching amplifier of example 15, wherein the fault detection circuitry is to set a value of the fault output based on comparison of the first DC offset to a threshold and comparison of the second DC offset to the threshold.

Example 18 includes the switching amplifier of example 17, wherein the threshold is programmable based on a type of the switching amplifier.

Example 19 includes the switching amplifier of example 17, wherein the fault detection circuitry is to set the value of the fault output to indicate the detection of the short in response to a magnitude of at least one of the first DC offset or the second DC offset satisfying the threshold.

Example 20 includes the switching amplifier of example 19, wherein the fault output includes a terminal and a register, and the fault detection circuitry is to set a value of the terminal to indicate the detection of the short in response to the magnitude of at least one of the first DC offset or the second DC offset satisfying the threshold, set the register to first register value to indicate the short is between the positive amplifier output and power in response to a polarity of the first DC offset being negative, set the register to a second register value to indicate the short is between the positive amplifier output and ground in response to the polarity of the first DC offset being positive, set the register to a third register value to indicate the short is between the negative amplifier output and power in response to a polarity of the second DC offset being positive, and set the register to a fourth register value to indicate the short is between the negative amplifier output and ground in response to the polarity of the second DC offset being negative.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A circuit comprising:
short detection circuitry having an input adapted to be coupled to an output of an amplifier, and an output, to:
sense an output current from the output of the amplifier; and
filter a signal corresponding to the output current from the output of the amplifier to measure a direct current (DC) offset associated with the output current;
wherein the short detection circuitry output indicates a short at the output of the amplifier based on the DC offset.

2. The circuit of claim 1, wherein the short detection circuitry is to set a value of the short detection circuitry output based on comparison of the DC offset to a threshold.

3. The circuit of claim 2, wherein the threshold is programmable based on a type of the amplifier.

4. The circuit of claim 2, wherein the short detection circuitry output includes a terminal, and the short detection circuitry is set a value of the terminal to indicate the short in response to a magnitude of the DC offset satisfying the threshold.

5. The circuit of claim 4, wherein amplifier is a switching amplifier, the short detection circuitry output includes a register, and the short detection circuitry is to set a value of the register based on a polarity of the DC offset to indicate whether the short is from the output of the amplifier to power or ground.

6. The circuit of claim 1, wherein the amplifier is a switching amplifier, the output of the amplifier is a positive output of the amplifier, the short detection circuitry input is a first short detection circuitry input adapted to be coupled to the positive output of the switching amplifier, the output current is a first output current associated with the positive output of the switching amplifier, the signal is a first signal corresponding to the first output current, the DC offset is a first DC offset associated with the first output current, and further including a second short detection circuitry input adapted to be coupled to a negative output of the switching amplifier, wherein the short detection circuitry is to:
sense a second output current from the negative output of the switching amplifier;
filter a second signal corresponding to the second output current to measure a second DC offset associated with the second output current; and
set the short detection circuitry output based on comparison of the first DC offset to a threshold and comparison of the second DC offset to the threshold.

7. The circuit of claim 6, wherein the short detection circuitry output includes a terminal and a register, and the short detection circuitry is to:
set a value of the terminal to indicate the short in response to at least one of a magnitude of the first DC offset satisfying the threshold or a magnitude of the second DC offset satisfying the threshold;
set the register to a first register value to indicate the short is between the positive output of the amplifier and power in response to a polarity of the first DC offset being negative;
set the register to a second register value to indicate the short is between the positive output of the amplifier and ground in response to the polarity of the first DC offset being positive;
set the register to a third register value to indicate the short is between the negative output of the amplifier and power in response to a polarity of the second DC offset being positive; and
set the register to a fourth register value to indicate the short is between the negative output of the amplifier and ground in response to the polarity of the second DC offset being negative.

8. The circuit of claim 6, wherein the short detection circuitry is to repeatedly switch between (i) sensing the first output current from the positive output of the switching amplifier, filtering the first signal corresponding to the first output current to measure the first DC offset, and setting the short detection circuitry output based on the comparison of the first DC offset to the threshold, and (ii) sensing the second output current from the negative output of the switching amplifier, filtering the second signal corresponding to the second output current to measure the second DC offset, and setting the short detection circuitry output based on the comparison of the second DC offset to the threshold.

9. A switching amplifier comprising:
a positive amplifier output;
a negative amplifier output; and
short detection circuitry including:
current sense circuitry having a first current sense input, a first current sense output, a second current sense input, and a second current sense output;
multiplexer circuitry having a first multiplexer input to couple to the first current sense output, a second multiplexer input to couple to the second current sense output, and a multiplexer output;
filter circuitry to filter a signal generated on the multiplexer output to measure a direct current (DC) offset associated with the multiplexer output; and
fault detection circuitry having a fault output to indicate a short on at least one of the positive amplifier output or the negative amplifier output, wherein the fault detection circuitry determines the fault output based on the DC offset.

10. The switching amplifier of claim 9, further including timing circuitry to synchronize operation of the multiplexer circuitry and the fault detection circuitry to cause the fault output to correspond to the positive amplifier output when the multiplexer output is connected to the first multiplexer input and correspond to the negative amplifier output when the multiplexer output is connected to the second multiplexer input.

11. The switching amplifier of claim 9, wherein the signal is an analog signal and further including:
an analog-to-digital converter to convert the analog signal to a first digital signal; and
decimation circuitry to down-sample a sampling rate of the first digital signal to generate a second digital signal,
wherein the filter circuitry is to filter the second digital signal to measure the DC offset.

12. The switching amplifier of claim 9, wherein the fault detection circuitry is to set a value of the fault output based on comparison of the DC offset to a threshold.

13. The switching amplifier of claim 12, wherein the threshold is a first programmable threshold that is programmable based on a type of the switching amplifier, and the fault detection circuitry is to set the value of the fault output based on comparison of the DC offset to the first programmable threshold and a second programmable threshold, wherein the second programmable threshold is programmable based on the type of the switching amplifier.

14. The switching amplifier of claim 9, wherein the fault output includes at least one of a register or a plurality of terminals, and the fault detection circuitry is to:
set the at least one of the register or the plurality of terminals to a first value to indicate the short is between the positive amplifier output and power;
set the at least one of the register or the plurality of terminals to a second value to indicate the short is between the positive amplifier output and ground;
set the at least one of the register or the plurality of terminals to a third value to indicate the short is between the negative amplifier output and power; and
set the at least one of the register or the plurality of terminals to a fourth value to indicate the short is between the positive amplifier output and ground.

15. A switching amplifier comprising:
short detection circuitry including:
first current sense circuitry having a first current sense input and a first current sense output, the first current sense input coupled to a positive amplifier output, the first current sense output to output a first sensed current associated with the positive amplifier output;
second current sense circuitry having a second current sense input and a second current sense output, the second current sense input coupled to a negative amplifier output, the second current sense output to output a second sensed current associated with the negative amplifier output;
first filter circuitry to filter a first signal generated on the first current sense output to measure a first direct current (DC) offset associated with the first sensed current;
second filter circuitry to filter a second signal generated on the second current sense output to measure a second DC offset associated with the second sensed current; and
fault detection circuitry having a fault output to indicate detection of a short on at least one of the positive amplifier output or the negative amplifier output, wherein the fault detection circuitry determines the fault output based on the first DC offset and the second DC offset.

16. The switching amplifier of claim 15, wherein the first signal is a first analog signal, the second signal is a second analog signal, and further including:
a first analog-to-digital converter to convert the first analog signal to a first digital signal;
a second analog-to-digital converter to convert the second analog signal to a second digital signal;
first decimation circuitry to down-sample a sampling rate of the first digital signal to generate a third digital signal, wherein the first filter circuitry is to filter the third digital signal to measure the first DC offset; and
second decimation circuitry to down-sample a sampling rate of the second digital signal to generate a fourth digital signal, wherein the second filter circuitry is to filter the fourth digital signal to measure the second DC offset.

17. The switching amplifier of claim 15, wherein the fault detection circuitry is to set a value of the fault output based on comparison of the first DC offset to a threshold and comparison of the second DC offset to the threshold.

18. The switching amplifier of claim 17, wherein the threshold is programmable based on a type of the switching amplifier.

19. The switching amplifier of claim 17, wherein the fault detection circuitry is to set the value of the fault output to indicate the detection of the short in response to a magnitude of at least one of the first DC offset or the second DC offset satisfying the threshold.

20. The switching amplifier of claim 19, wherein the fault output includes a terminal and a register, and the fault detection circuitry is to:
set a value of the terminal to indicate the detection of the short in response to the magnitude of at least one of the first DC offset or the second DC offset satisfying the threshold;
set the register to first register value to indicate the short is between the positive amplifier output and power in response to a polarity of the first DC offset being negative;
set the register to a second register value to indicate the short is between the positive amplifier output and ground in response to the polarity of the first DC offset being positive;
set the register to a third register value to indicate the short is between the negative amplifier output and power in response to a polarity of the second DC offset being positive; and
set the register to a fourth register value to indicate the short is between the negative amplifier output and ground in response to the polarity of the second DC offset being negative.
